(19) United States
(12) Patent Application Publication
(10) Pub. No.: US 2025/0191880 A1
(43) Pub. Date: Jun. 12, 2025

(54) PLASMA PROCESSING APPARATUS

(71) Applicant: Tokyo Electron Limited, Tokyo (JP)

(72) Inventor: Yohei YAMAZAWA, Miyagi (JP)

(73) Assignee: Tokyo Electron Limited, Tokyo (JP)

(21) Appl. No.: 19/053,434

(22) Filed: Feb. 14, 2025

Related U.S. Application Data
(63) Continuation of application No. PCT/JP2023/028861, filed on Aug. 8, 2023.

(30) Foreign Application Priority Data
Aug. 22, 2022 (JP) 2022-131975

(51) Int. Cl. H01J 37/32

(52) U.S. Cl. CPC H01J 37/32146; H01J 37/32174; H01J 37/32935; H01J 2237/334

(57) ABSTRACT

A plasma processing apparatus includes: a chamber; a substrate support including a RF electrode; a first RF power supply for generating a first pulsed RF signal; a second RF power supply for generating a second pulsed RF signal; a Vpp detector for detecting a bias Vpp value between the second RF power supply and the RF electrode; and a controller for executing: setting at least two power levels of each of the first pulsed RF signal and the second pulsed RF signal; determining plurality of phases in one pulse cycle; setting a bias Vpp target value in at least one of the plurality of phases; acquiring a representative value of the bias Vpp value in each phase; and adjusting the power level of at least one of the first or second pulsed RF signal in at least one selected phase so that the representative value reaches the target value.

### CROSS-REFERENCE TO RELATED APPLICATIONS

This application is a bypass continuation application of international application No. PCT/JP2023/028861 having an international filing date of Aug. 8, 2023 and designating the United States, the international application being based upon and claiming the benefit of priority from Japanese Patent Application No. 2022-131975, filed on Aug. 22, 2022, the entire contents of which are incorporated herein by reference.

### TECHNICAL FIELD

The present disclosure relates to a plasma processing apparatus.

### BACKGROUND

In a plasma processing apparatus, for example, a radio frequency (RF) voltage is supplied to a substrate as a processing target, thereby attracting ions or radicals generated from plasma into the substrate and executing a process such as etching. At this time, a voltage (Vpp) in the substrate is monitored and recorded as a process state indicator, and is used for process result prediction, state monitoring, abnormality detection, and the like. Further, there has been proposed monitoring a peak voltage value of a pulsed RF bias voltage to perform a feedback control (Patent Document 1).

### PRIOR ART DOCUMENT

### [Patent Document]

Patent Document 1: Japanese Laid-Open Patent Publication No. 2010-054614
Patent Document 2: U.S. Patent Application Publication No. 2015/0262704

### SUMMARY

According to one embodiment of the present disclosure, a plasma processing apparatus includes: a chamber; a substrate support disposed in the chamber and including a radio-frequency (RF) electrode; a first RF power supply coupled to the chamber and configured to generate a first pulsed RF signal having at least two power levels in each of a plurality of pulse cycles; a second RF power supply coupled to the RF electrode and configured to generate a second pulsed RF signal having at least two power levels in each of the plurality of pulse cycles; a voltage (Vpp) detector configured to detect a bias Vpp value between the second RF power supply and the RF electrode; and a controller. The controller is configured to perform: (a1) setting the at least two power levels of the first pulsed RF signal; (a2) setting the at least two power levels of the second pulsed RF signal; (b) determining a plurality of phases in one pulse cycle of the plurality of pulse cycles, wherein a state of at least one of the first pulsed RF signal or the second pulsed RF signal in each of the plurality of phases differs from a state in an adjacent phase; (c) setting a bias Vpp target value in at least one phase selected from the plurality of phases determined in (b); (d) acquiring a representative value of the bias Vpp value detected by the Vpp detector in each of the plurality of phases; and (e) adjusting the power level of at least one of the first pulsed RF signal or the second pulsed RF signal in the at least one selected phase so that the representative value of the bias Vpp value reaches the bias Vpp target value, based on the power levels set in each of (a1) and (a2) and the representative value of the bias Vpp value acquired in (d).

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating an example of a plasma processing system according to a first embodiment of the present disclosure.

FIG. 2 is a block diagram illustrating an example of a functional configuration of a controller according to the first embodiment.

FIG. 3 is a diagram illustrating an example of a configuration of a gauge according to the first embodiment.

FIG. 4 is a diagram illustrating an example of determining a bias phase from recipe settings.

FIG. 5 is a diagram illustrating an example of a method of picking up points within a certain range from a phase average for each phase and acquiring an average value.

FIG. 6 is a diagram illustrating an example of acquiring a sequence based on a delay time in a determined phase, an average acquisition time, and a synchronization signal.

FIG. 7 is a diagram illustrating an example of specifying a level based on a one-dimensional cluster analysis method.

FIG. 8 is a diagram illustrating an example of a relationship between a square of Vpp and a bias power level in a square response method.

FIG. 9 is a diagram illustrating an example of a timing chart according to the first embodiment.

FIG. 10 is a flowchart illustrating an example of adjustment processing according to the first embodiment.

FIG. 11 is a diagram illustrating an example of a timing chart according to a second embodiment.

FIG. 12 is a diagram illustrating an example of a plasma processing system according to a third embodiment.

FIG. 13 is a diagram illustrating an example of a timing chart according to the third embodiment.

FIG. 14 is a flowchart illustrating an example of adjustment processing according to the third embodiment.

FIG. 15 is a diagram illustrating an example of a timing chart according to a fourth embodiment.

FIG. 16 is a diagram illustrating an example of a timing chart according to Modification 1 of the fourth embodiment.

FIG. 17 is a diagram illustrating an example of a timing chart according to Modification 2 of the fourth embodiment.

FIG. 18 is a diagram illustrating an example of a computer that executes an adjustment program.

### DETAILED DESCRIPTION

Hereinafter, embodiments of a plasma processing apparatus disclosed herein will be described in detail with reference to the drawings. In addition, the disclosed technique is not limited by the following embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

A voltage (Vpp) value is closely relating to the acceleration energy of ions during a plasma process. For example, the Vpp value may fluctuate depending on a load state of plasma when bias power that draws ions into a substrate is controlled to remain constant. To address this, it is conceivable to control the bias power so that the Vpp value remains constant, thereby aligning the ion energy to a desired level. Further, when the plasma or bias power is pulsed, it is conceivable to use multi-level pulses, thereby enabling fine-tuning of the process by utilizing ion energies. With the use of multi-level pulses, for example, etching is performed on a relatively high energy side, deposition is performed on a relatively low energy side, and discharge is promoted at an off time. To enhance the stability of the process using the multi-level pulses, it is necessary to control, for each level of the multi-level pulses, the bias power so that the Vpp value remains constant, thereby enabling the precise control of ion energy in the pulsed plasma. Therefore, it is necessary to control the bias power to keep the Vpp value constant and to enhance the process stability.

### First Embodiment

### [Configuration of Plasma Processing System]

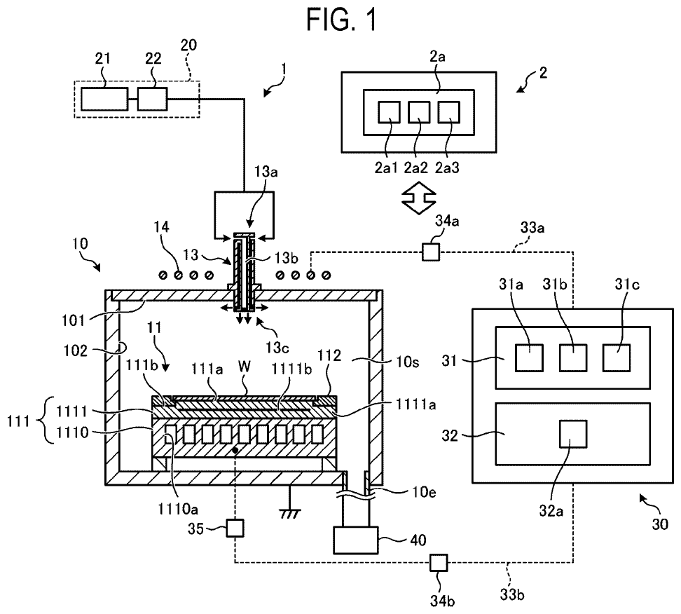

Hereinafter, an example of a configuration example of a plasma processing system will be described. FIG. 1 is a diagram illustrating an example of the plasma processing system according to a first embodiment of the present disclosure. As illustrated in FIG. 1, the plasma processing system includes an inductively coupled plasma processing apparatus 1 and a controller 2. The inductively coupled plasma processing apparatus 1 includes a plasma processing chamber 10, a gas supply 20, a power supply 30, and an exhaust system 40. The plasma processing chamber 10 includes a dielectric window 101. Further, the plasma processing apparatus 1 includes a substrate support 11, a gas introduction unit, and an antenna 14. The substrate support 11 is disposed in the plasma processing chamber 10. The antenna 14 is positioned on or above the plasma processing chamber 10 (that is, on or above the dielectric window 101). The plasma processing chamber 10 has a plasma processing space 10s defined by the dielectric window 101, a sidewall 102 of the plasma processing chamber 10, and the substrate support 11. The plasma processing chamber 10 includes at least one gas supply port for supplying at least one processing gas into the plasma processing space 10s, and at least one gas discharge port for discharging the gas from the plasma processing space 10s. The plasma processing chamber 10 is grounded.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 to surround the substrate W on the central region 111a of the main body 111. Thus, the central region 111a is also referred to as a substrate support surface for supporting the substrate W. The annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a and an electrostatic electrode 1111b embedded in the ceramic member 1111a. The ceramic member 1111a has the central region 111a. In one embodiment, the ceramic member 1111a also has the annular region 111b. In addition, another member surrounding the electrostatic chuck 1111, such as an annular electrostatic chuck or an annular insulating member, may have the annular region 111b.

In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power supply 31 and/or a direct current (DC) power supply 32, which will be described later, may be embedded in the ceramic member 1111a. In this case, the at least one RF/DC electrode functions as a bias electrode. In addition, the conductive member of the base 1110 and the at least one RF/DC electrode may function as a plurality of bias electrodes. Further, the electrostatic electrode 1111b may function as a bias electrode. Accordingly, the substrate support 11 includes at least one bias electrode.

The ring assembly 112 includes one or more annular members. In one embodiment, the one or more annular members include one or more edge rings and at least one covering. The edge ring is made of a conductive material or an insulating material, and the covering is made of an insulating material.

Further, the substrate support 11 may include a temperature regulation module configured to regulate at least one of the electrostatic chuck 1111, the ring assembly 112, or the substrate to a target temperature. The temperature regulation module may include a heater, a heat transfer medium, a flow path 1110a, or a combination thereof. A heat transfer fluid such as brine or gas flows through the flow path 1110a. In one embodiment, the flow path 1110a is formed in the base 1110, and one or more heaters are embedded in the ceramic member 1111a of the electrostatic chuck 1111. Further, the substrate support 11 may include a heat transfer gas supply configured to supply a heat transfer gas to a gap between a back surface of the substrate W and the central region 111a.

The gas introduction unit is configured to introduce at least one processing gas from the gas supply 20 into the plasma processing space 10s. In one embodiment, the gas introduction unit includes a center gas injector (CGI) 13. The center gas injector 13 is positioned above the substrate support 11 and is installed in a central opening formed in the dielectric window 101. The center gas injector 13 includes at least one gas supply port 13a, at least one gas flow path 13b, and at least one gas inlet 13c. The processing gas supplied to the gas supply port 13a passes through the gas flow path 13b and is introduced into the plasma processing space 10s via the gas inlet 13c. In addition to or instead of the center gas injector 13, the gas introduction unit may further include one or more side gas injectors (SGI) installed in one or more openings formed in the sidewall 102.

The gas supply 20 may include at least one gas source 21 and at least one flow controller 22. In one embodiment, the gas supply 20 is configured to supply at least one processing gas from a respective gas source 21 to the gas introduction unit via a respective flow controller 22. Each flow controller 22 may include, for example, a mass flow controller or a pressure-controlled flow controller. Further, the gas supply 20 may include one or more flow modulation devices that modulate or pulse a flow of at least one processing gas.

The power supply 30 includes the RF power supply 31 coupled to the plasma processing chamber 10 via at least one impedance matching circuit. The RF power supply 31 is configured to supply at least one RF signal (RF power) to at least one bias electrode and the antenna 14. As a result, a plasma is generated from at least one processing gas supplied to the plasma processing space 10s. Thus, the RF power supply 31 may function as at least a portion of a plasma generator configured to generate the plasma from one or more processing gases in the plasma processing chamber 10. Further, when a bias RF signal is supplied to at least one bias electrode, a bias potential occurs in the substrate W and ions in the generated plasma is drawn into the substrate W.

In one embodiment, the RF power supply 31 includes a first RF generator 31a and a second RF generator 31b. Further, the RF power supply 31 may include a synchronization signal generator 31c. The first RF generator 31a is coupled to the antenna 14 and is configured to generate a source RF signal (source RF power) for plasma generation via at least one impedance matching circuit. In one embodiment, the source RF signal has a frequency within a range of 10 MHz to 150 MHz. In one embodiment, the first RF generator 31a may be configured to generate a plurality of source RF signals with different frequencies. The generated source RF signals are supplied to the antenna 14. In addition, the first RF generator 31a is an example of a first RF power supply.

The second RF generator 31b is coupled to at least one bias electrode via at least one impedance matching circuit, and is configured to generate a bias RF signal (bias RF power). A frequency of the bias RF signal may be the same as or different from the frequency of the source RF signal. In one embodiment, the bias RF signal has a lower frequency than that of the source RF signal. In one embodiment, the bias RF signal has a frequency within a range of 100 kHz to 60 MHz. In one embodiment, the second RF generator 31b may be configured to generate a plurality of bias RF signals with different frequencies. The generated bias RF signals are supplied to at least one bias electrode. Further, in various embodiments, at least one of the source RF signal or the bias RF signal may be pulsed. In addition, the second RF generator 31b is an example of a second RF power supply.

The synchronization signal generator 31c generates a synchronization signal for synchronizing the first RF generator 31a and the second RF generator 31b. When the generated synchronization signal is supplied from the synchronization signal generator 31c to the first RF generator 31a and the second RF generator 31b, for example, the pulsed source RF signal and bias RF signal are synchronized with each other. Further, the synchronization signal generator 31c supplies the synchronization signal to the controller 2, so that the synchronization signal is used as a timing signal in the adjustment processing of RF signals executed by the controller 2.

For example, the first RF generator 31a is electrically connected to the antenna 14 via a conductor 33a such as wiring. The conductor 33a is provided with an impedance matching circuit 34a. The impedance matching circuit 34a matches an output impedance of the first RF generator 31a with an input impedance on a load side (the antenna 14). In addition, the impedance matching circuit 34a is an example of a first matcher. The first RF generator 31a supplies the source RF signal for plasma generation to the antenna 14.

Further, for example, the second RF generator 31b is electrically connected to the conductive member of the base of the substrate support 11 via a conductor 33b such as wiring. The conductor 33b is provided with an impedance matching circuit 34b. The impedance matching circuit 34b matches an output impedance of the second RF generator 31b with an input impedance on a load side (the substrate support 11). In addition, the impedance matching circuit 34b is an example of a second matcher. The second RF generator 31b supplies a bias RF signal to the conductive member of the substrate support 11 in order to draw ions in the plasma into the substrate W.

The plasma processing apparatus 1 includes a gauge 35 provided on an electrode disposed in the plasma processing chamber 10 or wiring connected to the electrode to measure a voltage or a current. In the present embodiment, the gauge 35 is provided on the conductor 33b connected to the conductive member of the substrate support 11. The gauge 35 includes a probe for detecting the voltage or the current, and is configured to measure the voltage or the current. The gauge 35 measures a voltage or current of the conductor 33b through which the bias RF signal flows, and outputs a signal indicating the measured voltage or current to the controller 2 to be described later. In addition, the gauge 35 is an example of a Vpp detector.

Further, the power supply 30 may include the DC power supply 32 coupled to the plasma processing chamber 10. The DC power supply 32 includes a bias DC generator 32a. In one embodiment, the bias DC generator 32a is connected to at least one bias electrode, and is configured to generate a bias DC signal. The generated bias DC signal is applied to at least one bias electrode.

In various embodiments, the bias DC signal may be pulsed. In this case, a sequence of voltage pulses is applied to at least one bias electrode. The voltage pulses may have a rectangular, trapezoidal, or triangular pulse waveform, or a combination thereof. In one embodiment, a waveform generator for generating the sequence of voltage pulses from the DC signal is connected between the bias DC generator 32a and at least one bias electrode. Thus, the bias DC generator 32a and the waveform generator constitute a voltage pulse generator. The voltage pulses may have positive polarity or negative polarity. Further, the sequence of voltage pulses may include one or more positive-polarity voltage pulses or one or more negative-polarity voltage pulses in one cycle. In addition, the bias DC generator 32a may be provided in addition to the RF power supply 31, or may be provided instead of the second RF generator 31b.

The antenna 14 includes one or more coils. In one embodiment, the antenna 14 may include an outer coil and an inner coil, which are arranged coaxially with each other. In this case, the RF power supply 31 may be connected to both the outer coil and the inner coil, or to either the outer coil or the inner coil. In the former case, the same RF generator may be connected to both the outer coil and the inner coil, or separate RF generators may be connected separately to the outer coil and the inner coil.

The exhaust system 40 may be connected to, for example, a gas discharge port 10e provided at the bottom of the plasma processing chamber 10. The exhaust system 40 may include a pressure adjustment valve and a vacuum pump. An internal pressure of the plasma processing space 10s is adjusted by the pressure adjustment valve. The vacuum pump may include a turbo-molecular pump, a dry pump, or a combination thereof.

The controller 2 processes computer-executable instructions for causing the plasma processing apparatus 1 to execute various operations described in the present disclosure. The controller 2 may be configured to control individual constituent elements of the plasma processing apparatus 1 so as to execute various operations described herein. In one embodiment, a part or all of the controller 2 may be included in the plasma processing apparatus 1. The controller 2 may include a processor 2a1, a storage 2a2, and an external interface 2a3. The controller 2 is implemented by, for example, a computer 2a. The processor 2a1 may be configured to perform various control operations by reading a program from the storage 2a2 and executing the read program. The program may be stored in advance in the storage 2a2, or may be acquired via a medium when necessary. The acquired program is stored in the storage 2a2, and is read from the storage 2a2 to be executed by the processor 2a1. The medium may be any of various non-transitory computer-readable storage media readable by the computer 2a, or may be a communication line connected to the external interface 2a3. The processor 2a1 may be a central processing unit (CPU). The storage 2a2 may include a random access memory (RAM), a read only memory (ROM), a hard disk drive (HDD), a solid state drive (SSD), or a combination thereof. The external interface 2a3 may communicate with the plasma processing apparatus 1 via a communication line such as a local area network (LAN).

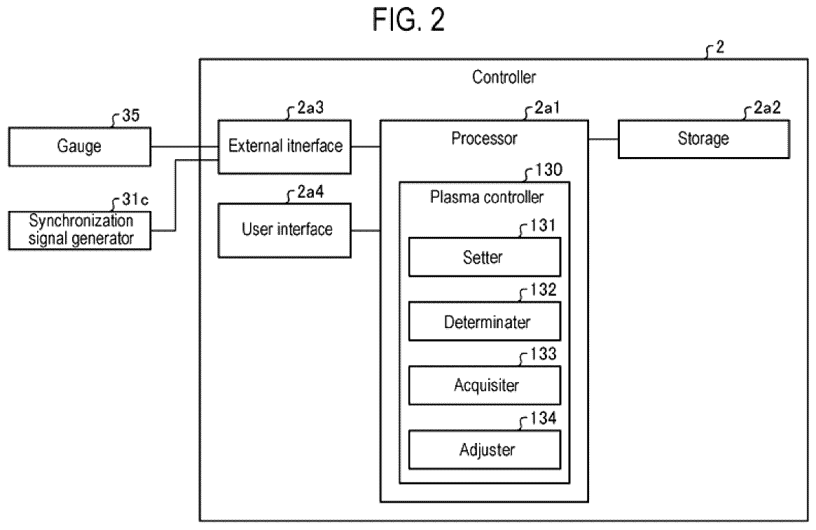

Next, a functional configuration of the controller 2 will be described with reference to FIG. 2. FIG. 2 is a block diagram illustrating an example of the functional configuration of the controller according to the first embodiment. The controller 2 controls individual constituent elements of the plasma processing apparatus 1. The operation of the plasma processing apparatus 1 is comprehensively controlled by the controller 2. The controller 2 performs control to cause the plasma processing apparatus 1 to execute various operations described in the present disclosure. As illustrated in FIG. 2, the controller 2 includes the processor 2a1, the storage 2a2, the external interface 2a3, and a user interface 2a4.

The processor 2a1 includes a CPU to control individual constituent elements of the plasma processing apparatus 1.

The storage 2a2 stores a control program (software) for implementing various types of processing executed in the plasma processing apparatus 1 under the control of the processor 2a1, as well as a recipe that stores processing condition data and other information. In addition, the control program and recipe may be stored in a non-transitory computer-readable computer recording medium (for example, a hard disk, an optical disc such as a digital versatile disc (DVD), a flexible disk, or a semiconductor memory). Further, the control program and recipe may also be transmitted at any time from another device, for example, via a dedicated line, and may be used online.

The external interface 2a3 is capable of communicating with individual constituent elements of the plasma processing apparatus 1, performing the input and output of various pieces of data. For example, signals indicating the voltage and current measured by the gauge 35 are input to the external interface 2a3. Further, the synchronization signal generated by the synchronization signal generator 31c is input to the external interface 2a3.

The user interface 2a4 includes a keyboard for inputting commands by the process manager to manage the plasma processing apparatus 1, and a display for visualizing and displaying an operational status of the plasma processing apparatus 1.

The processor 2a1 includes an internal memory for storing programs and data. The processor 2a1 reads the control program stored in the storage 2a2, and executes the processing of the read control program. The processor 2a1 functions as various processors by operating the control program. For example, the processor 2a1 has the function of a plasma controller 130.

The plasma controller 130 controls plasma processing. For example, the plasma controller 130 controls the exhaust system 40 to exhaust an interior of the plasma processing chamber 10 to be kept at a predetermined vacuum level. The plasma controller 130 controls the gas supply 20 to introduce the processing gas from the gas supply 20 into the plasma processing space 10s. The plasma controller 130 controls the power supply 30 to supply the source RF signal and the bias RF signal from the first RF generator 31a and the second RF generator 31b, respectively, to generate plasma inside the plasma processing chamber 10 in accordance with the introduction of the processing gas.

The plasma processing apparatus 1 according to the present embodiment performs, for example, cycle etching. The plasma controller 130 controls the RF power supply 31 to supply the radio-frequency power in a pulse-like manner from the RF power supply 31. The RF power supply 31 supplies at least one of the source RF signal or the bias RF signal in a pulse-like manner. For example, the plasma controller 130 controls the RF power supply 31 to supply the source RF signal and the bias RF signal from the first RF generator 31a and the second RF generator 31b, respectively, in a pulse-like manner. Here, the expression “supply in a pulse-like manner” includes turning on and off the supply of the source RF signal and the bias RF signal in a certain pattern. Further, the expression “supply in a pulse-like manner” also includes repeating a plurality of power levels (High/Low/Off) of the source RF signal and the bias RF signal in a certain pattern. In other words, each of the source RF signal and the bias RF signal has a plurality of power levels in a repetition cycle. In one embodiment, the plurality of power levels include a first power level and a second power level smaller than the first power level. In one embodiment, the plurality of power levels include a first power level, a second power level smaller than the first power level, and a third power level smaller than the second power level. The third power level may be a zero power level, or may be greater than the zero power level. The pulse frequency is, for example, within a range of 100 Hz to 10 kHz. Hereinafter, among the source RF signal and the bias RF signal, the source RF signal with a relatively high frequency is also referred to as high frequency (HF), and the bias RF signal with a relatively low frequency is also referred to as low frequency (LF).

Further, the plasma controller 130 controls at least one of the first RF generator 31a or the second RF generator 31b to adjust the power level of at least one of the source RF signal or the bias RF signal so that a Vpp value calculated from the signal input from the gauge 35 reaches a set Vpp value. To adjust these power levels, the plasma controller 130 includes a setter 131, a determiner 132, an acquisiter 133, and an adjuster 134.

The setter 131 reads a recipe from the storage 2a2, and sets a power level of at least one of the source RF signal or the bias RF signal based on the recipe. The setter 131 sets at least two power levels of the source RF signal generated by the first RF generator 31a. In addition, the source RF signal is an example of a first pulsed RF signal. Further, the setter 131 sets at least two power levels of the bias RF signal generated by the second RF generator 31b. In addition, the bias RF signal is an example of a second pulsed RF signal. Further, one of the two power levels set for the source RF signal or the bias RF signal may be a zero power level. The setter 131 stores the power level of at least one of the source RF signal or the bias RF signal in the storage 2a2.

The determiner 132 specifies a pulse cycle based on the recipe. The determiner 132 may specify a pulse cycle of bias Vpp values based on the synchronization signal input from the synchronization signal generator 31c. Further, the determiner 132 determines a plurality of phases in a single pulse cycle based on the recipe using a method to be described later. The determiner 132 detects a bias Vpp representative value for each phase in a specified single pulse cycle. Further, for example, the determiner 132 may specify bias Vpp values of each level using a one-dimensional cluster analysis method to be described later, and may detect a Vpp representative value for each phase based on a correspondence between each level and a phase set by a user. Further, each level thus set is expressed, for example, in the ascending order of bias Vpp values, for example, as level L1 and level L2. Further, in the following description, a series of data used to obtain an average of the bias Vpp values for each level in the pulse-like manner of the signal measured by the gauge 35 is referred to as a sequence.

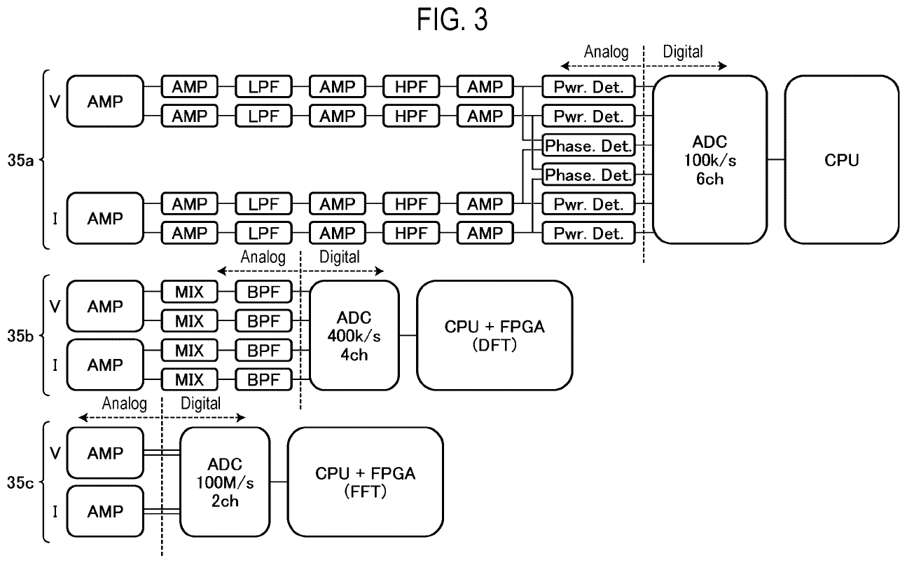

Here, processing from the acquisition of the bias Vpp values to the determination of the bias phase will be described with reference to FIGS. 3 to 7. FIG. 3 is a diagram illustrating an example of a configuration of the gauge according to the first embodiment. As illustrated in FIG. 3, the gauge 35 may use methods such as Configurations 35a to 35c to digitize analog measurement values. In addition, in Configurations 35a to 35c, to measure two types of frequencies (for example, 13 MHz and 400 kHz) in the second RF generator 31b, a voltage and current are detected in two systems.

Configuration 35a detects a voltage, current, and phase using an analog detection integrated circuit (IC), and digitizes them with an analog/digital (A/D) converter. In Configuration 35a, for example, an A/D converter with a sampling frequency of 100 kHz and 6 channels (100 k/s and 6 ch) is used. Digital data output from the A/D converter is input to the plasma controller 130 (CPU in FIG. 3).

Configuration 35b combines heterodyne and in-phase quadrature-phase (IQ) detection, converts a signal to an intermediate frequency, and subsequently digitizes the same with an A/D converter. In Configuration 35b, for example, an A/D converter with a sampling frequency of 400 kHz and 4 channels (400 k/s and 4 ch) is used. Digital data output from the A/D converter is input to the plasma controller 130 (CPU and field programmable gate array (FPGA) in FIG. 3). In addition, the CPU and FPGA perform a signal process using Discrete Fourier Transform (DFT).

Configuration 35c is a full digital method of digitizing an analog signal using an A/D converter. In Configuration 35c, for example, an A/D converter with a sampling frequency of 100 MHz and 2 channels (100 M/s and 2 ch) is used. Digital data output from the A/D converter is input to the plasma controller 130 (CPU and FPGA in FIG. 3). In addition, the CPU and FPGA perform a signal process using Fast Fourier Transform (FFT). In other words, Configuration 35c performs high-speed sampling at more than twice the RF frequency and outputs the amplitude by FFT applied to a certain number of data.

The gauge 35 uses any of the above three methods to acquire signals, corresponding to current and voltage amplitudes and phase differences, at a high speed in a continuous manner over a period of at least one pulse cycle, with a sampling rate greater than or equal to 10 times a pulse frequency. The gauge 35 calculates a Vpp value at each time point from the current and voltage amplitude and phase difference acquired at each time point. In this way, continuous Vpp time-series data over a period of at least one pulse cycle is obtained.

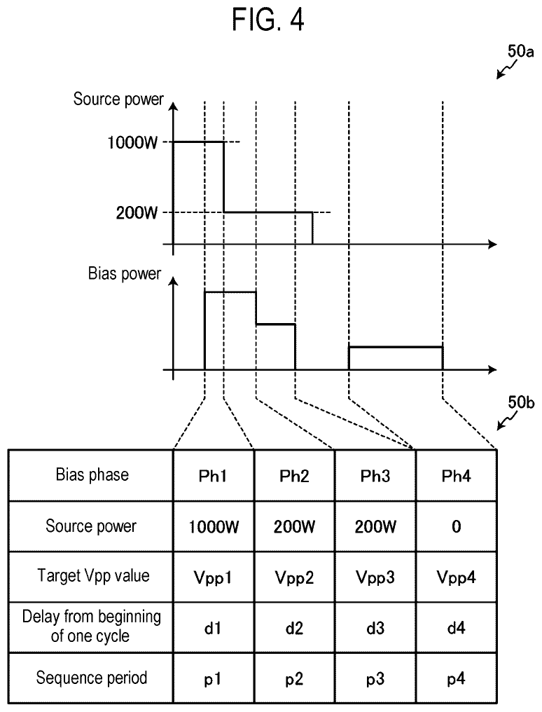

FIG. 4 is a diagram illustrating an example of determining a bias phase from recipe settings. Timing chart 50a of FIG. 4 illustrates a case in which the source RF signal (source power) is supplied together with the bias RF signal (bias power). Table 50b summarizes each phase when both the source RF signal and the bias RF signal are supplied. In other words, FIG. 4 illustrates a case in which a phase is determined from the ON/OFF status and power level combinations of the first RF generator 31a and the second RF generator 31b. In this case, the determiner 132 switches the phase at least at the ON/OFF switching timing of the second RF generator 31b (the bias RF signal). Further, the determiner 132 switches the phase at a timing when a bias Vpp value needs to be changed.

A method of obtaining a Vpp representative value for each phase from the Vpp time-series data will be described. The simplest method is to use, as a representative value, the average of a plurality of Vpp values, acquired from the start to the end of each phase, based on the synchronization signal and phase information. This method has the advantage of being able to be executed quickly with simple calculations but may be affected by transient states during phase switching, causing fluctuations in values.

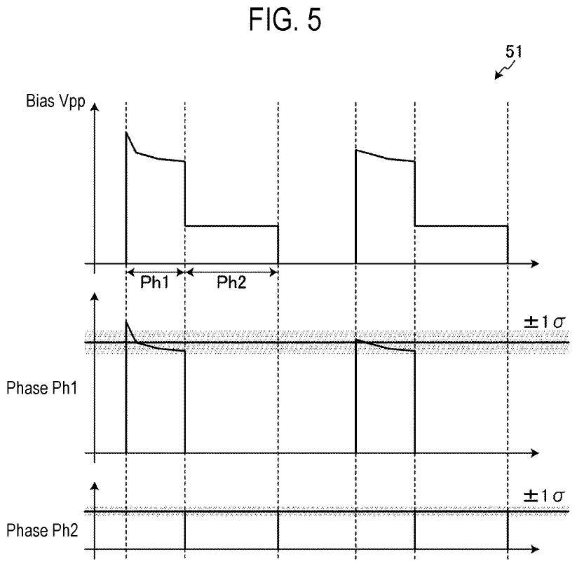

Therefore, the average of the plurality of Vpp values acquired from the start to the end of each phase is obtained. Subsequently, only values within a certain range (for example, 1×standard deviation or 2×standard deviation) from the average are collected to obtain the average of the collected values. This makes it possible to acquire an average value excluding values that significantly deviate from a first average value obtained in a first round of operation, that is, transient values. FIG. 5 is a diagram illustrating an example of a method of picking up points within a certain range from the phase average for each phase and acquiring an average value. As illustrated in timing chart 51 of FIG. 5, only values within a range of 1×standard deviation from the average of phase Ph1 (a range of ±1σ of phase Ph1 in FIG. 5) are collected, and the average of the collected values is acquired. Further, only values within a range of 1×standard deviation from the average of phase Ph2 (a range of ±1σ of phase Ph2 in FIG. 5) are collected, and the average of the collected values is acquired.

There is another method of excluding values in transient states (transient values) include setting a delay period at the beginning of each phase, and obtaining the average of a plurality of Vpp values acquired during a certain time after a delay time in each phase. The determiner 132 determines, based on a process recipe, the turn-on period of the second RF generator 31b, that is, a target Vpp value for each phase, a delay time from the beginning of one cycle, and an average acquisition period.

In the example of FIG. 4, in bias phase Ph1, power of the source RF signal (source power in FIG. 4) is set to 1,000 W, a target Vpp value is set to Vpp1, delay (delay time) from the beginning of one cycle is set to d1, and a sequence period is set to p1. Similarly, in bias phase Ph2, source power is set to 200 W, a target Vpp value is set to Vpp2, delay from the beginning of one cycle is set to d2, and a sequence period is set to p2. In bias phase Ph3, source power is set to 200 W, a target Vpp value is set to Vpp3, delay from the beginning of one cycle is set to d3, and a sequence period is set to p3. Further, in bias phase Ph4, source power is set to 0 W, a target Vpp value is set to Vpp4, delay from the beginning of one cycle is set to d4, and a sequence period is set to p4. In addition, in the example of FIG. 4, a period during which the bias RF signal is zero is not considered as a phase.

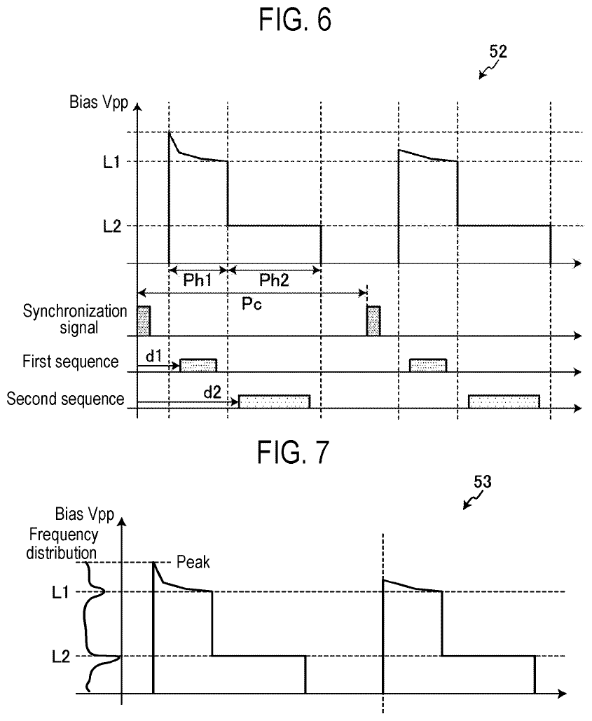

FIG. 6 is a diagram illustrating an example of acquiring a sequence based on a delay time in a determined phase, an average acquisition time, and a synchronization signal. As illustrated in timing chart 52 of FIG. 6, the determiner 132 determines delay times d1 and d2 in phases Ph1 and Ph2 and periods for acquiring first and second sequences based on the synchronization signal. In the example of FIG. 6, the first sequence corresponds to level L1, and the second sequence corresponds to level L2.

FIG. 7 is a diagram illustrating an example of specifying a level based on a one-dimensional cluster analysis method. This method obtains Vpp values for each level by using the average of data points within a certain range from level values excluding transient values, based on Vpp frequency distribution when the synchronization signal is not obtained. Timing chart 53 of FIG. 7 illustrates a case of specifying levels L1 and L2 from the frequency distribution of the bias Vpp values using the one-dimensional cluster analysis method. The determiner 132 divides waveform data of the bias Vpp values over an entire single pulse cycle (entire sequence, first data group) into a plurality of groups based on, for example, an average value. In addition, the entire sequence corresponds to a pulse cycle Pc in timing chart 52. The determiner 132 extracts a second data group included in a valid group from the divided groups, and obtains a statistical value for each group based on the extracted second data group. The determiner 132 specifies levels L1 and L2 based on the statistical value for each group. This makes it possible to obtain the representative value by excluding transient states far from the average and using only stable states close to the average.

Returning to FIG. 4, the determiner 132 associates the measured bias Vpp values with bias phases Ph1 to Ph4. When a delay time is known, the determiner 132 associates the measured bias Vpp value with a corresponding phase based on the delay time. On the other hand, when no delay time is known, the determiner 132 associates the measured bias Vpp value with a corresponding phase based on the pulse order of the measured bias Vpp value and the measured value. Further, the determiner 132 may receive association data based on the bias Vpp values and the pulse order expected from the process recipe, which is input by a process manager.

Returning to the description of FIG. 2, once the determiner 132 has determined each phase in a single pulse cycle, the delay time, and the sequence acquisition period, the acquisiter 133 acquires a sequence of bias Vpp values for each phase. In other words, the acquisiter 133 acquires a sequence of the plurality of bias Vpp values (a data group of bias Vpp values) detected by the gauge 35 after the delay time in each phase. At this time, the acquisiter 133 may repeatedly acquire the sequence across a plurality of pulse cycles. In other words, the acquisiter 133 may continuously acquire the sequence at regular intervals. Further, the acquisiter 133 may acquire the sequence in a cycle greater than or equal to 10 times the pulse frequency of the plurality of pulse cycles. This may improve resolution. The acquisiter 133 obtains a representative value of the bias Vpp values from the acquired sequence of the bias Vpp values. In other words, the acquisiter 133 acquires the representative value of the bias Vpp values detected by the gauge 35 for each of the plurality of phases. The acquisiter 133 outputs the acquired representative value of the bias Vpp values to the adjuster 134.

When the representative value of the bias Vpp values is input from the acquisiter 133, the adjuster 134 acquires the set power level of at least one of the source RF signal or the bias RF signal with reference to the storage 2a2. In other words, the adjuster 134 sets a target value of the bias Vpp values in at least one phase selected from determined phases. The adjuster 134 adjusts, based on the set power level and the representative value of the bias Vpp values, the power level of at least one of the source RF signal or the bias RF signal for each phase to set the target value of the bias Vpp values. In other words, the adjuster 134 controls, for each phase, the first RF generator 31a and the second RF generator 31b to adjust the power levels of the source RF signal and the bias RF signal so that the input average of the sequence of bias Vpp values, that is, the representative value, approaches a target Vpp value (Vpp setting value).

The adjuster 134 employs, for example, proportional integral differential (PID) control to adjust the power level of at least one of the source RF signal or the bias RF signal. In this case, no assumption is made especially about a relationship between the bias Vpp value and the power level. In addition, control parameters may be changed depending on process conditions.

Further, for example, the adjuster 134 may adjust the power level of at least one of the source RF signal or the bias RF signal through the control based on the relationship between the bias Vpp value and the power level. In this case, the adjuster 134 predicts a next power level using a relationship that the bias power level is proportional to the square of the bias Vpp value. This adjustment method differs from the PID control which assumes a linear response, in that it assumes a square response and controls by ratios instead of increments. In the following description, this adjustment method is also referred to as “square response (Sq. Response) method”. In the square response method, the next power level (RF_Powerₙ) is predicted by Equations (1) to (3) below.

k=SV²/PV² (1)

k>k_{MAX}⇒k=k_{MAX} (2)

RF_Powerₙ=RF_Power_{n-1×(}1+(k−1)×VppControlCoefficient) (3)

Where, PV represents the Vpp measurement value, SV represents the Vpp setting value, and k_{MAX} represents the upper limit of k. Further, VppControlCoefficient represents the damping coefficient.

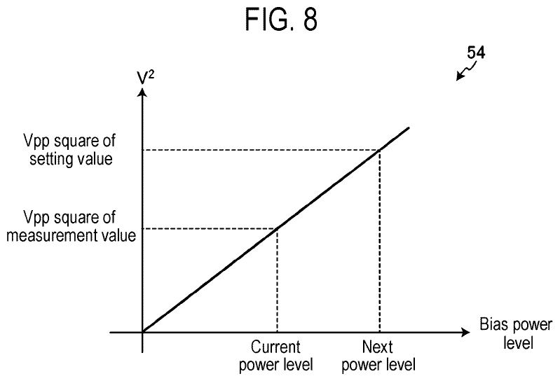

Next, a relationship between the square of Vpp and a bias power level in the square response method will be described with reference to FIG. 8. FIG. 8 is a diagram illustrating an example of the relationship between the square of Vpp and the bias power level in the square response method. In graph 54 of FIG. 8, the square of Vpp is represented as “V²”. Further, a bias power level P may be represented by Equation (4) below. In addition, Equation (4) is another form of Equations (1) to (3) above.

P=R(V/Z)² (4)

Where, R represents the load resistance, and Z represents the load impedance. In Equation (4), assuming that R and Z are constant, the calculation of the bias power level to obtain a desired Vpp value uses the ratio of the square of V, as illustrated in graph 54, rather than the ratio of V. In other words, the squared response method uses the relationship illustrated in graph 54 to adjust the current power level to the next power level so that the square of the Vpp measurement value approaches the square of the Vpp setting value.

### [Timing Chart Relating to First Embodiment]

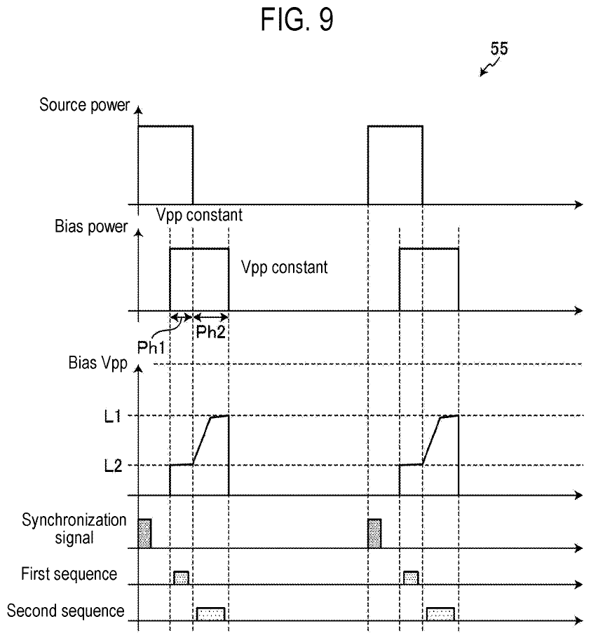

Next, a pulse waveform in the first embodiment will be described with reference to FIG. 9. FIG. 9 is a diagram illustrating an example of a timing chart according to the first embodiment. In timing chart 55 illustrated in FIG. 9, the source RF signal (source power) and the bias RF signal (bias power) are supplied at different timings. Each of the source RF signal and the bias RF signal exhibits a first power level (High) and a zero level. Further, in timing chart 55, the bias RF signal is adjusted so that the bias Vpp value remains constant.

In timing chart 55, the source RF signal and the bias RF signal are synchronized with each other by a synchronization signal (for example, 1 kHz). Further, in timing chart 55, there is an overlapping portion of the source RF signal and the bias RF signal, and bias Vpp values exhibit three levels: levels L1 and L2 and a zero level. In other words, the bias Vpp value level L1 is a combination of the zero level of the source RF signal and the first power level of the bias RF signal. Further, the bias Vpp value level L2 is a combination of the first power level of the source RF signal and the first power level of the bias RF signal. Thus, bias phases are phases Ph1 and Ph2 corresponding to levels L1 and L2, respectively. In other words, the state of at least one of the source RF signal or the bias RF signal in each of the plurality of phases differs from that in an adjacent phase. Further, in phases Ph1 and Ph2, a first sequence and a second sequence are acquired based on the synchronization signal (timing signal).

### [Adjustment Method of First Embodiment]

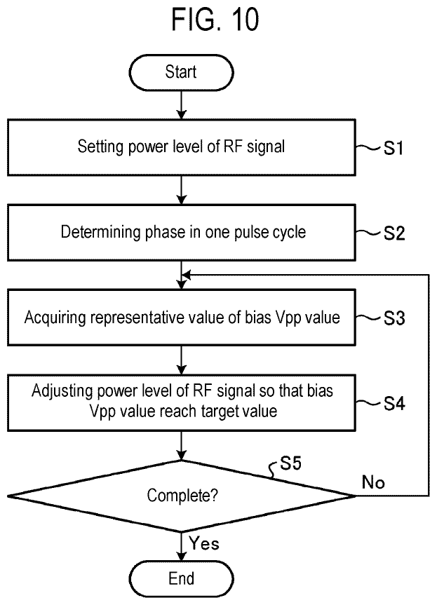

Next, an adjustment method of the first embodiment will be described with reference to FIG. 10. FIG. 10 is a flowchart illustrating an example of an adjustment processing according to the first embodiment.

In the adjustment processing according to the first embodiment, a case in which plasma processing is performed on the substrate W placed on the central region 111a of the main body 111 of the substrate support 11 in the plasma processing apparatus 1 will be described by way of example, but the description of operations relating to the plasma processing other than the adjustment processing by the plasma controller 130 will be omitted.

The setter 131 reads the recipe from the storage 2a2, and sets the power levels of the source RF signal and the bias RF signal for the first RF generator 31a and the second RF generator 31b based on the recipe (Step S1). The power levels of the source RF signal and the bias RF signal set by the setter 131 are stored in the storage 2a2. Thereafter, the plasma controller 130 controls individual constituent elements of the plasma processing apparatus 1 to start the plasma processing.

The determiner 132 specifies a pulse cycle of the bias Vpp values based on the synchronization signal input from the synchronization signal generator 31c and the bias Vpp values input from the gauge 35. The determiner 132 detects the bias Vpp values of each level in the specified single pulse cycle to specify each level. The determiner 132 determines a plurality of phases in the specified single pulse cycle based on the synchronization signal and each specified level (Step S2). Further, the determiner 132 determines a delay time in each phase and a detection period (period for acquiring a sequence) of a plurality of bias Vpp values based on the synchronization signal.

Once the determiner 132 has determined each phase in the single pulse cycle, the delay time, and the sequence acquisition period, the acquisiter 133 acquires the sequence of the bias Vpp values for each phase (Step S3). The acquisiter 133 obtains the representative value of the bias Vpp values from the acquired sequence of the bias Vpp values. In other words, the acquisiter 133 acquires the representative value of the bias Vpp values detected by the gauge 35 for each of a plurality of phases. The acquisiter 133 outputs the acquired representative value of the bias Vpp values to the adjuster 134.

When the representative value of the bias Vpp values is input from the acquisiter 133, the adjuster 134 acquires the set power level of the bias RF signal with reference to the storage 2a2. In other words, the adjuster 134 sets a target value of the bias Vpp values in at least one phase selected from determined phases. The adjuster 134 adjusts, based on the set power level and the representative value of the bias Vpp values, the power level of the bias RF signal for each phase to set a target value of the bias Vpp values. In other words, the adjuster 134 controls, for each phase, the second RF generator 31b to adjust the power level of the bias RF signal so that the input bias Vpp value reaches a target value (Step S4). In addition, the expression “so that the input bias Vpp value reaches a target value” is another way of saying that the average of the sequence of the bias Vpp values, that is, the representative value, approaches the target Vpp value (Vpp setting value) as described above. Further, the adjuster 134 may control the first RF generator 31a to adjust the power level of the source RF signal.

The adjuster 134 determines whether or not to complete the adjustment processing based on the adjustment result of the power level of the bias RF signal (Step S5). In other words, the adjuster 134 determines whether or not the bias Vpp value has reached the target value, which would indicate that the adjustment processing may be completed. When the adjuster 134 determines that the adjustment processing is not yet completed (Step S5: NO), the process returns to Step S3 and continues to adjust the power level of the bias RF signal. On the other hand, when the adjuster 134 determines that the adjustment processing is completed (Step S5: “YES”), the adjustment processing ends. Thus, the bias power may be controlled so that the Vpp value reaches the target value (constant value). In other words, it is possible to enhance the process stability.

### Second Embodiment

In the above first embodiment, each of the source RF signal and the bias RF signal has been described to have two levels, but these signals may be multi-leveled to three or more, and this case will be described as a second embodiment. In addition, a plasma processing apparatus according to the second embodiment is similar to that according to the first embodiment described above, and therefore, duplicate descriptions of configurations and operations will be omitted.

### [Timing Chart Relating to Second Embodiment]

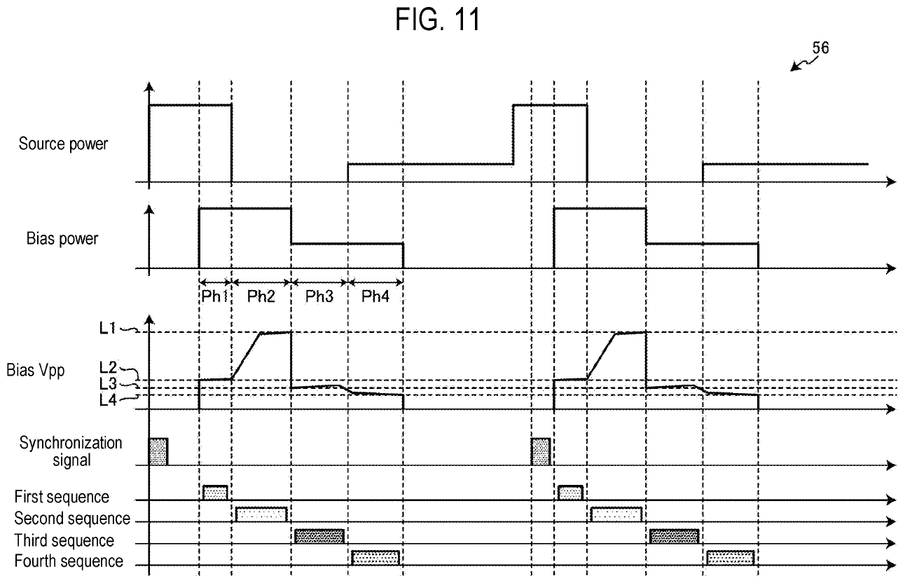

FIG. 11 is a diagram illustrating an example of a timing chart according to the second embodiment. In timing chart 56 illustrated in FIG. 11, a multi-leveled source RF signal (source power) and bias RF signal (bias power) are supplied at different timings. Each of the source RF signal and the bias RF signal has two-stage power levels such as a first power level (High) and a second power level (Low), and a zero level (third power level). Further, in timing chart 56, the bias RF signal is adjusted so that bias Vpp values remain constant for levels L1 and L2.

In timing chart 56, the source RF signal and the bias RF signal are synchronized with each other by a synchronization signal. Further, in timing chart 56, there is an overlapping portion of the source RF signal and the bias RF signal for each level, and the bias Vpp values exhibit five levels: levels L1 to L4 and a zero level. In other words, the bias Vpp value level L1 is a combination of the zero level of the source RF signal and the first power level of the bias RF signal. Further, the bias Vpp value level L2 is a combination of the first power level of the source RF signal and the first power level of the bias RF signal. Further, the bias Vpp value level L3 is a combination of the zero level of the source RF signal and the second power level of the bias RF signal. Further, the bias Vpp value level L4 is a combination of the second power level of the source RF signal and the second power level of the bias RF signal. Thus, the bias phases are phases Ph1 to Ph4 corresponding to levels L1 to L4, respectively. Further, in phases Ph1 to Ph4, first to fourth sequences are acquired based on the synchronization signal (timing signal).

The adjuster 134 controls the second RF generator 31b to adjust the bias RF signal so that the bias Vpp values for levels L1 and L2 remain constant based on each set power level of the bias RF signal and the acquired first and second sequences. Further, the adjuster 134 controls the second RF generator 31b to adjust the bias RF signal so that an input power of the bias Vpp values for levels L3 and L4 remains constant based on each set power level of the bias RF signal and the acquired third and fourth sequences.

The adjustment processing in the second embodiment is similar to that in the first embodiment as illustrated in the flowchart of FIG. 10, except for a difference in the number of sequences, and therefore, description thereof will be omitted. According to the second embodiment, even when the source RF signal and the bias RF signal are multi-leveled, the bias power may be controlled so that a desired phase Vpp value remains constant.

### Third Embodiment

In the above second embodiment, the bias RF signal had a single frequency, but bias RF signals with two frequencies may be supplied. This case will be described as a third embodiment.

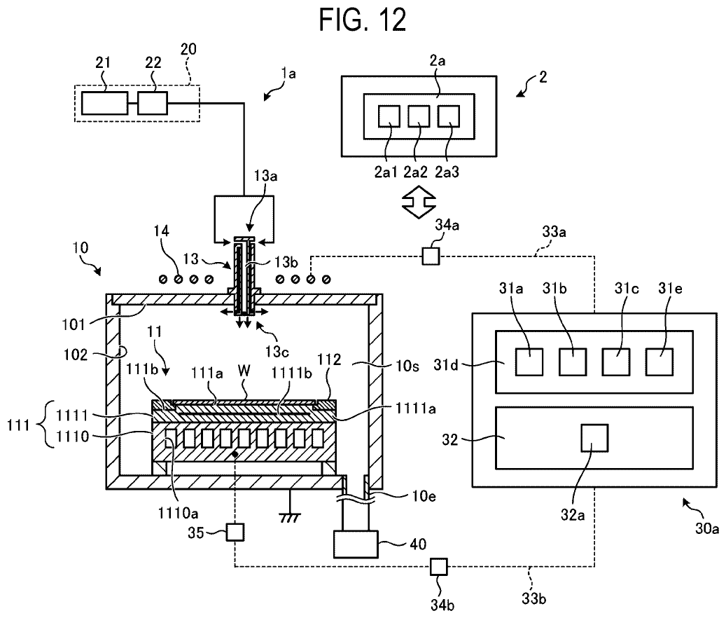

FIG. 12 is a diagram illustrating an example of a plasma processing system according to a third embodiment. In addition, the same reference numerals will be given to the same components as those in the plasma processing system of the first embodiment, and duplicate descriptions of configurations and operations will be omitted. A plasma processing apparatus 1a of the third embodiment differs from the plasma processing apparatus 1 of the first embodiment in that the RF power supply 31 includes a third RF generator.

The plasma processing apparatus 1a of the third embodiment includes a power supply 30a. The power supply 30a includes an RF power supply 31d and the DC power supply 32. The RF power supply 31d includes the first RF generator 31a, the second RF generator 31b, the synchronization signal generator 31c, and a third RF generator 31e.

Similar to the second RF generator 31b, the third RF generator 31e is coupled to at least one bias electrode via at least one impedance matching circuit, and is configured to generate a second bias RF signal (bias RF power). In addition, in the third embodiment, the bias RF signal generated by the second RF generator 31b is referred to as a first bias RF signal. A frequency of the second bias RF signal may be the same as or different from the frequency of the source RF signal. Further, the frequency of the second bias RF signal differs from the frequency of the first bias RF signal. Further, similar to the second RF generator 31b, the third RF generator 31e is electrically connected to the conductive member of the base of the substrate support 11 via the conductor 33b such as wiring.

In one embodiment, the second bias RF signal has a lower frequency than those of the source RF signal and the first bias RF signal. In one embodiment, the second bias RF signal has a frequency within a range of 100 kHz to 60 MHz. For example, the frequency of the first bias RF signal may be 13 MHz, and the frequency of the second bias RF signal may be 400 kHz. In one embodiment, the third RF generator 31e may be configured to be included in the second RF generator 31b. The generated second bias RF signal is supplied to at least one bias electrode. Further, in various embodiments, at least one of the source RF signal, the first bias RF signal, or the second bias RF signal may be pulsed. In addition, the third RF generator 31e is an example of a third RF power supply.

### [Timing Chart Relating to Third Embodiment]

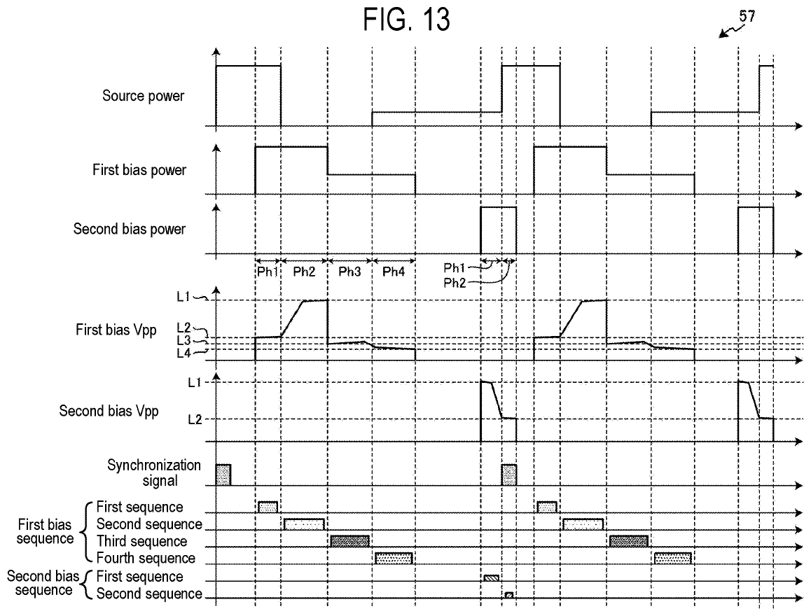

FIG. 13 is a diagram illustrating an example of a timing chart according to the third embodiment. In timing chart 57 illustrated in FIG. 13, a multi-leveled source RF signal (source power), first bias RF signal (first bias power), and second bias RF signal (second bias power) are supplied at different timings. Each of the source RF signal and the bias RF signal has two-stage power levels such as a first power level (High) and a second power level (Low), and a zero level (third power level). Further, the second bias RF signal exhibits the first power level (High) and the zero level.

Further, in timing chart 57, the second bias RF signal is adjusted so that second bias Vpp values of the second bias RF signal for levels L1 and L2 remain constant. Further, in timing chart 57, the bias RF signal is adjusted so that an input power of first bias Vpp values of the first bias RF signal for levels L1 to L4 remain constant. Further, the first bias RF signal may be adjusted so that bias Vpp values for levels L1 and L2 remain constant. Further, the source RF signal may be continuous wave (CW).

In timing chart 57, the source RF signal, the first bias RF signal, and the second bias RF signal are synchronized with each other by a synchronization signal. Further, in timing chart 57, there is a portion where the source RF signal, the first bias RF signal, and the second bias RF signal for each level overlap each other. Therefore, in timing chart 57, the first bias Vpp values corresponding to the first bias RF signal exhibit five levels such as levels L1 to L4 and a zero level. Further, similarly, in timing chart 57, the second bias Vpp values corresponding to the second bias RF signal exhibit three power levels such as levels L1 and L2 and a zero level.

In other words, the first bias Vpp value level L1 is a combination of the zero level of the source RF signal and the first power level of the first bias RF signal. Further, the first bias Vpp value level L2 is a combination of the first power level of the source RF signal and the first power level of the first bias RF signal. Further, the first bias Vpp value level L3 is a combination of the zero level of the source RF signal and the second power level of the first bias RF signal. Further, the first bias Vpp value level L4 is a combination of the second power level of the source RF signal and the second power level of the first bias RF signal. Further, the second bias Vpp value level L1 is a combination of the second power level of the source RF signal and the first power level of the second bias RF signal. Further, the second bias Vpp value level L2 is a combination of the first power level of the source RF signal and the first power level of the second bias RF signal.

Thus, the bias phases are phases Ph1 to Ph4 that correspond to levels L1 to L4 of the first bias Vpp values, respectively, and phases Ph1 and Ph2 that correspond to levels L1 and L2 of the second bias Vpp values, respectively. Further, in phases Ph1 to Ph4 of the first bias Vpp values, first to fourth sequences of the first bias Vpp values are obtained based on a synchronization signal (timing signal). Similarly, in phases Ph1 and Ph2 of the second bias Vpp values, first and second sequences of the second bias Vpp values are obtained based on a synchronization signal (timing signal).

### [Adjustment Method of Third Embodiment]

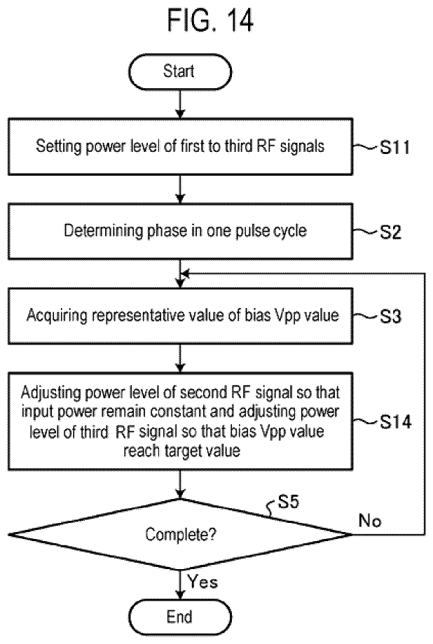

Next, an adjustment method of the third embodiment will be described with reference to FIG. 14. FIG. 14 is a flowchart illustrating an example of adjustment processing according to the third embodiment.

In the adjustment processing according to the third embodiment, a case in which plasma processing is performed on the substrate W placed on the central region 111a of the main body 111 of the substrate support 11 in the plasma processing apparatus 1a will be described by way of example, but descriptions of operations relating to the plasma processing other than the adjustment processing by the plasma controller 130 will be omitted.

The setter 131 reads a recipe from the storage 2a2, and sets the power levels of the source RF signal, the first bias RF signal, and the second bias RF signal, that is, first to third RF signals, for the first RF generator 31a, the second RF generator 31b, and the third RF generator 31e based on the recipe (Step S11). The power levels of the first to third RF signals set by the setter 131 are stored in the storage 2a2. Thereafter, the plasma controller 130 controls individual constituent elements of the plasma processing apparatus 1a to start the plasma processing. The plasma controller 130 executes the processing of Steps S2 and S3 following Step S11.

When representative values of respective bias Vpp values corresponding to the second and third RF signals are input from the acquisiter 133, the adjuster 134 acquires the set power levels of the second and third RF signals with reference to the storage 2a2. In other words, the adjuster 134 sets target values of the respective bias Vpp values corresponding to the second and third RF signals for at least one phase selected from determined phases. The adjuster 134 adjusts the power level of the second RF signal for each phase so that an input power remains constant based on the set power level of the second RF signal and each representative value of the corresponding bias Vpp values. Further, the adjuster 134 adjusts the power level of the third RF signal for each phase so that each bias Vpp value reaches a target value based on the set power level of the third RF signal and each representative value of the corresponding bias Vpp values. In other words, the adjuster 134 controls the second RF generator 31b to adjust the power level of the second RF signal for each phase of the second RF signal so that an input power remains constant, and controls the second RF generator 31b to adjust the power level of the third RF signal for each phase of the third RF signal so that the input bias Vpp value reaches a target value (Step S14). The adjuster 134 may control the first RF generator 31a to adjust the power level of the source RF signal. The plasma controller 130 executes the processing of Step S5 following Step S14. Thus, even when two types of frequencies are used as bias RF signals, the bias power may be controlled so that a desired phase Vpp value reaches a target value (constant value).

### Fourth Embodiment

In the above-described first embodiment, each of the source RF signal and the bias RF signal has been described to have two levels, but the bias RF signal may be multi-leveled while the source RF signal is the continuous wave (CW) or not supplied. This case will be described as a fourth embodiment. In addition, a plasma processing apparatus according to the fourth embodiment is similar to that according to the first embodiment described above, and therefore, duplicate descriptions of configurations and operations will be omitted.

### [Timing Chart Relating to Fourth Embodiment]

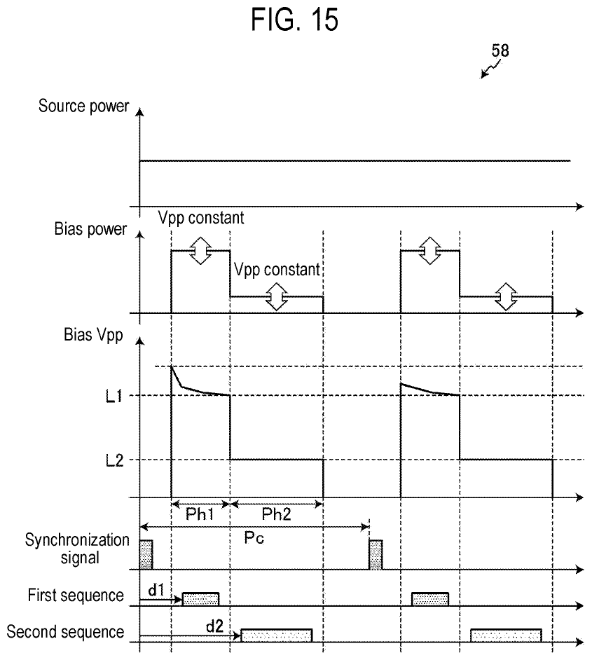

FIG. 15 is a diagram illustrating an example of a timing chart according to the fourth embodiment. In timing chart 58 illustrated in FIG. 15, the source RF signal (source power) is supplied as CW and the multi-leveled bias RF signal (bias power) is supplied. The bias RF signal exhibits two-stage power levels such as a first power level (High) and a second power level (Low), and a zero level (third power level). Further, in timing chart 58, the bias RF signal is adjusted so that bias Vpp values for levels L1 and L2 remain constant (constant Vpp).

In timing chart 58, the synchronization signal generated by the synchronization signal generator 31c is utilized as a timing signal corresponding to a single pulse cycle Pc of the bias RF signal. Further, in timing chart 58, a bias Vpp value corresponding to the bias RF signal for each level exhibits three levels such as levels L1 and L2, and a zero level. In other words, the bias RF signal has first and second power levels (High/Low) corresponding to the bias Vpp value levels L1 and L2 excluding the zero level. Thus, the bias phases are phases Ph1 and Ph2 corresponding to levels L1 and L2, respectively. Further, in phases Ph1 and Ph2, first and second sequence are acquired based on the synchronization signal (timing signal). In other words, the first sequence corresponds to a plurality of bias Vpp values (data group) acquired after a delay time d1 in phase Ph1. Similarly, the second sequence corresponds to a plurality of bias Vpp values (data group) acquired after a delay time d2 in phase Ph2.

The adjuster 134 controls the second RF generator 31b to adjust the bias RF signal so that bias Vpp values for levels L1 and L2 remain constant based on each set power level of the bias RF signal and the acquired first and second sequences. In addition, in timing chart 58, a portion where the bias Vpp value exhibits the zero level will also be determined as a phase. In this case, the portion where the bias Vpp value is at the zero level corresponds to a third sequence. Further, when the bias RF signal is set to more power levels, a phase corresponding to each power level is determined.

The adjustment processing in the fourth embodiment is similar to that in the first embodiment as illustrated in FIG. 10, except for a difference in whether or not the source RF signal is pulsed, and therefore, descriptions thereof will be omitted. According to the fourth embodiment, the bias power may be controlled so that a desired phase Vpp value remains constant even when the source RF signal is either CW or not supplied.

### Modification 1 of Fourth Embodiment

In the fourth embodiment, the bias RF signal has been described to be adjusted so that the bias Vpp values corresponding to phases Ph1 and Ph2 of the bias RF signal remain constant for levels L1 and L2, respectively, but the bias RF signal may be adjusted so that an input power of one of them remains constant. This case will be described as Modification 1 of the fourth embodiment. In addition, a plasma processing apparatus according to Modification 1 of the fourth embodiment is similar to that according to the first embodiment described above, and therefore, duplicate descriptions of configurations and operations will be omitted.

### [Timing Chart Relating to Modification 1 of Fourth Embodiment]

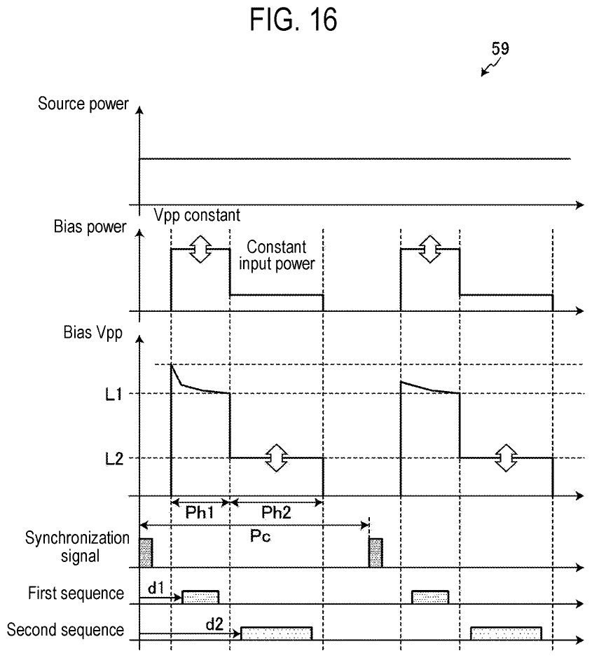

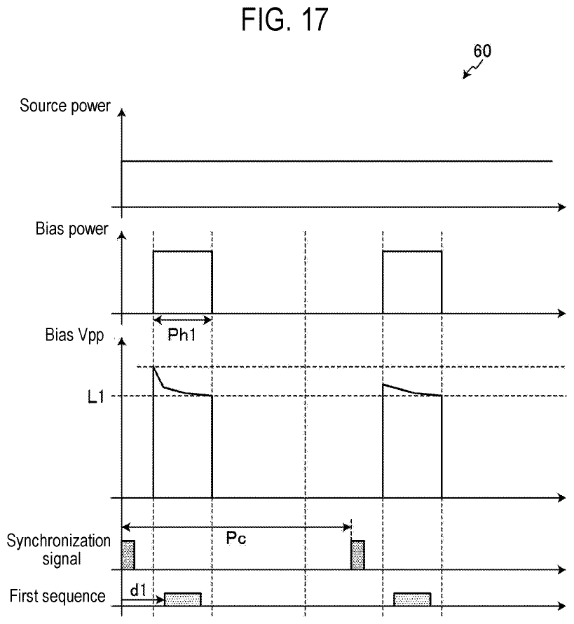

FIG. 16 is a diagram illustrating an example of a timing chart according to Modification 1 of the fourth embodiment. In timing chart 59 illustrated in FIG. 16, the source RF signal (source power) is supplied as CW and the multi-leveled bias RF signal (bias power) is supplied. The bias RF signal exhibits two-stage power levels such as a first power level (High) and a second power level (Low), and a zero level (third power level). Further, in timing chart 59, the bias RF signal is adjusted so that bias Vpp values for level L1 remain constant (constant Vpp). Further, the bias RF signal is adjusted such that input power of bias Vpp values for level L2 remains constant (constant input power).

In timing chart 59, the synchronization signal generated by the synchronization signal generator 31c is utilized as a timing signal corresponding to a single pulse cycle Pc of the bias RF signal. Further, in timing chart 59, bias Vpp values corresponding to the bias RF signal for each power level exhibit three power levels such as levels L1 and L2, and a zero level. In other words, the bias RF signal has first and second power levels (High/Low) corresponding to the bias Vpp value levels L1 and L2 excluding the zero level. Thus, the bias phases are phases Ph1 and Ph2 corresponding to levels L1 and L2, respectively. Further, in phases Ph1 and Ph2, first and second sequences are acquired based on the synchronization signal (timing signal). In other words, the first sequence corresponds to a plurality of bias Vpp values (data group) acquired after the delay time d1 in phase Ph1. Similarly, the second sequence corresponds to a plurality of bias Vpp values (data group) acquired after the delay time d2 in phase Ph2.

The adjuster 134 controls the second RF generator 31b to adjust the bias RF signal so that bias Vpp values for level L1 remain constant based on each set power level of the bias RF signal and the acquired first sequence. Further, the adjuster 134 controls the second RF generator 31b to adjust the bias RF signal so that input power of bias Vpp values for level L2 remains constant based on each set power level of the bias RF signal and the acquired second sequence. In addition, similar to timing chart 58, a portion where the bias Vpp value exhibits the zero level will also be determined as a phase. In this case, the portion where the bias Vpp value is at the zero level corresponds to a third sequence. Further, when the bias RF signal is set to more power levels, a phase corresponding to each power level is determined. In this case, for each phase, whether or not the bias Vpp values remain constant or the input power remains constant may be determined arbitrarily.

The adjustment processing according to Modification 1 of the fourth embodiment is similar to that in the first embodiment as illustrated in the flowchart of FIG. 10, except for differences in that whether or not the source RF signal is pulsed, and the power level of the bias RF signal is adjusted so that the input power remains constant in some sequences, and therefore descriptions thereof will be omitted. According to Modification 1 of the fourth embodiment, the bias power may be controlled so that a desired phase Vpp value remains constant or the input power remains constant even when the source RF signal is either CW or not supplied.

### Modification 2 of Fourth Embodiment

In the fourth embodiment, the power level of the bias RF signal has been described to be set to two stage-power levels such as the first power level (High) and the second power level (Low), and the zero level, but it may also be set to the first power level (High) and the zero level. This case will be described as Modification 2 of the fourth embodiment. In addition, a plasma processing apparatus according to Modification 2 of the fourth embodiment is similar to that according to the first embodiment described above, and therefore, duplicate descriptions of configurations and operations will be omitted.

FIG. 17 is a diagram illustrating an example of a timing chart according to Modification 2 of the fourth embodiment. In timing chart 60 illustrated in FIG. 17, the source RF signal (source power) is supplied as CW and the bias RF signal (bias power) is supplied in a pulse-like manner. The bias RF signal has a first power level (High) and a zero level. Further, in timing chart 60, the bias RF signal is adjusted so that bias Vpp values for level L1 remain constant.

In timing chart 60, the synchronization signal generated by the synchronization signal generator 31c is utilized as a timing signal corresponding to a single pulse cycle Pc of the bias RF signal. Further, in timing chart 60, bias Vpp values corresponding to the bias RF signal exhibit two power levels such as level L1 and a zero level. In other words, the bias RF signal has a first power level (High) corresponding to the bias Vpp value level L1 excluding a zero level. Thus, the bias phase is phase Ph1 corresponding to level L1. Further, in phase Ph1, a first sequence is acquired based on the synchronization signal (timing signal). In other words, the first sequence corresponds to a plurality of bias Vpp values (data group) acquired after the delay time d1 in phase Ph1.

The adjuster 134 controls the second RF generator 31b to adjust the bias RF signal so that bias Vpp values for level L1 remain constant based on the set power level of the bias RF signal and the acquired first sequence. In addition, similar to timing chart 58, in timing chart 60, a portion where the bias Vpp value exhibits the zero level will also be determined as a phase. In this case, the portion where the bias Vpp value is at the zero level corresponds to a third sequence.

The adjustment processing according to Modification 2 of the fourth embodiment is similar to that in the first embodiment as illustrated in FIG. 10, except for a difference in whether or not the source RF signal is pulsed, and therefore, descriptions thereof will be omitted. According to Modification 2 of the fourth embodiment, the bias power may be controlled so that a desired phase Vpp value remains constant even when the source RF signal is either CW or not supplied.

In addition, the configurations of the first embodiment in which the acquisiter 133 may continuously acquire sequences at regular intervals and the acquisiter 133 may acquire sequences in a cycle greater than or equal to 10 times the pulse frequency of a plurality of pulse cycles, may be applied to the second embodiment and Modification 2 of the fourth embodiment. Similarly, each method of obtaining the Vpp representative value for each phase from the Vpp time-series data in the first embodiment may also be applied to the second embodiment and Modification 2 of the fourth embodiment.

Further, in each of the above embodiments, sequence determination may be performed using the synchronization signal or using the one-dimensional cluster analysis method.

As described above, according to the first embodiment, the plasma processing apparatus 1 includes the chamber (the plasma processing chamber 10), the substrate support 11 disposed in the chamber and including the RF electrode, the first RF power supply (the first RF generator 31a) coupled to the chamber and configured to generate the first pulsed RF signal having at least two power levels in each of the plurality of pulse cycles, the second RF power supply (the second RF generator 31b) coupled to the RF electrode and configured to generate the second pulsed RF signal having at least two power levels in each of the plurality of pulse cycles, the Vpp detector (the gauge 35) configured to detect the bias Vpp value between the second RF power supply and the RF electrode; and the controller 2. The controller 2 is configured to perform (a1) setting the at least two power levels of the first pulsed RF signal, (a2) setting the at least two power levels of the second pulsed RF signal, (b) determining a plurality of phases in one pulse cycle of the plurality of pulse cycles, wherein a state of at least one of the first pulsed RF signal or the second pulsed RF signal in each of the plurality of phases differs from that in an adjacent phase, (c) setting the bias Vpp target value in at least one phase selected from the plurality of phases determined in (b), (d) acquiring a representative value of the bias Vpp value detected by the Vpp detector in each of the plurality of phases, and (e) adjusting the power level of at least one of the first pulsed RF signal or the second pulsed RF signal in the at least one selected phase so that the representative value of the bias Vpp value reaches the target value, based on the power levels set in (a1) and (a2) and the representative value of the bias Vpp value acquired in (d). As a result, the process stability may be enhanced.

Further, according to the first embodiment, the representative value is an average value of bias Vpp values detected by the Vpp detector over an entire period of the phase. As a result, the accuracy of the representative value of the bias Vpp value may be enhanced.

Further, according to the first embodiment, the representative value is an average value of a plurality of bias Vpp values detected by the Vpp detector over a detection period after a delay time in the phase so that a bias Vpp value in a transient state is excluded from the plurality of bias Vpp values. As a result, the accuracy of the representative value of the bias Vpp value may be enhanced.

Further, according to the first embodiment, the representative value is an average value of selected bias Vpp values within a set Vpp range, among the plurality of bias Vpp values detected by the Vpp detector over an entire period of the phase so that a bias Vpp value in a transient state is excluded from the plurality of bias Vpp values. As a result, the accuracy of the representative value of the bias Vpp value may be enhanced.

Further, according to the first embodiment, the plurality of bias Vpp values are detected continuously at a regular interval. As a result, feedback control may be performed so that the Vpp value remains constant.

Further, according to the first embodiment, the plurality of bias Vpp values are detected in a cycle greater than or equal to 10 times a pulse frequency of the plurality of pulse cycles. As a result, the resolution of each level of the bias Vpp value and a noise removal performance may be improved.

Further, according to the first embodiment, the plasma processing apparatus 1 further includes the synchronization signal generator 31c configured to generate the synchronization signal for synchronizing the first RF power supply and the second RF power supply. The controller 2 is configured to perform determining the delay time and the detection period in the phase based on the synchronization signal. As a result, the bias power control may be easily performed to remain the Vpp value constant.

Further, according to the third embodiment, the plasma processing apparatus 1a includes: the chamber (the plasma processing chamber 10); the substrate support 11 disposed in the chamber and including the RF electrode; the first RF power supply (the first RF generator 31a) coupled to the chamber and configured to generate the first pulsed RF signal having at least two power levels in each of the plurality of pulse cycles, wherein the first pulsed RF signal has a first RF frequency; the second RF power supply (the second RF generator 31b) coupled to the RF electrode and configured to generate the second pulsed RF signal having at least two power levels in each of the plurality of pulse cycles, wherein the second pulsed RF signal has a second RF frequency; the third RF power supply (the third RF generator 31e) coupled to the RF electrode and configured to generate the third pulsed RF signal having at least two power levels in each of the plurality of pulse cycles, wherein the third pulsed RF signal has a third RF frequency; the Vpp detector (the gauge 35) configured to detect the bias Vpp value between the second RF power supply and the third RF power supply and the RF electrode; and the controller 2. The controller 2 is configured to perform (a1) setting the at least two power levels of the first pulsed RF signal, (a2) setting the at least two power levels of the second pulsed RF signal, (a3) setting the at least two power levels of the third pulsed RF signal, (b) determining a plurality of phases in one pulse cycle of the plurality of pulse cycles, wherein a state of at least one of the first pulsed RF signal, the second pulsed RF signal, or the third pulsed RF signal in each of the plurality of phases differs from that in an adjacent phase, (c) setting the bias Vpp target value of at least one of the second RF frequency or the third RF frequency in at least one phase selected from the plurality of phases determined in (b), (d) acquiring the representative value of the bias Vpp value of at least one of the second RF frequency or the third RF frequency detected by the Vpp detector in each of the plurality of phases, and (e) adjusting the power level of at least one of the first pulsed RF signal, the second pulsed RF signal, or the third pulsed RF signal in the at least one selected phase so that the representative value of the bias Vpp value of one of the second RF frequency and the third RF frequency reaches the target value, based on the power levels set in each of (a1) to (a3) and the representative value of the bias Vpp value of at least one of the second RF frequency or the third RF frequency acquired in (d). As a result, even if two types of bias RF power supplies are provided, the process stability may be enhanced.

Further, according to the third embodiment, the representative value is an average value of a plurality of bias Vpp values of one of the second RF frequency and the third RF frequency detected by the Vpp detector over an entire period of the phase. As a result, the accuracy of the representative value of the bias Vpp value may be enhanced.

Further, according to the third embodiment, the representative value is an average value of a plurality of bias Vpp values of one of the second RF frequency and the third RF frequency detected by the Vpp detector over a detection period after a delay time in the phase so that a bias Vpp value in a transient state is excluded from the plurality of bias Vpp values. As a result, the accuracy of the representative value of the bias Vpp value may be enhanced.

Further, according to the third embodiment, the representative value is an average value of selected bias Vpp values within a set Vpp range, among a plurality of bias Vpp values of one of the second RF frequency and the third RF frequency detected by the Vpp detector over an entire period of the phase so that a bias Vpp value in a transient state is excluded from the plurality of bias Vpp values. As a result, the accuracy of the representative value of the bias Vpp value may be enhanced.

Further, according to the third embodiment, the plasma processing apparatus 1a further includes the synchronization signal generator 31c configured to generate the synchronization signal for synchronizing the first RF power supply, the second RF power supply, and the third RF power supply. The controller 2 is configured to perform determining the delay time and the detection period in the phase based on the synchronization signal. As a result, the bias power control may be easily performed to remain the Vpp value constant.

Further, according to the third embodiment, the second pulsed RF signal is controlled so that the input power of the power level remains constant, and the third pulsed RF signal is controlled so that the bias Vpp value remains constant. As a result, the control of remaining the input power constant and the control of remaining the bias Vpp value constant for the bias RF signal may be combined with each other. Further, when varying the power level of the bias RF signal, RF matching may become unstable. In this case, by performing the control of remaining the input power constant, the process stability may further be enhanced.

Further, according to the third embodiment, the plasma processing apparatus 1a includes: the chamber (the plasma processing chamber 10); the substrate support 11 disposed in the chamber and including the RF electrode; the first RF power supply (the first RF generator 31a) coupled to the chamber and configured to generate the first RF signal, wherein the first RF signal has the first RF frequency; the second RF power supply (the second RF generator 31b) coupled to the RF electrode and configured to generate the second pulsed RF signal having at least two power levels in each of the plurality of pulse cycles, wherein the second pulsed RF signal has the second RF frequency; the Vpp detector (the gauge 35) configured to detect the bias Vpp value between the second RF power supply and the RF electrode; and the controller 2. The controller 2 is configured to perform (a1) setting the power level of the first RF signal, (a2) setting the at least two power levels of the second pulsed RF signal, (b) determining a plurality of phases in one pulse cycle of the plurality of pulse cycles, wherein a state of the second pulsed RF signal in each of the plurality of phases differs from that in an adjacent phase, (c) setting the bias Vpp target value of the second RF frequency in at least one phase selected from the plurality of phases determined in (b), (d) acquiring the representative value of the bias Vpp value of the second RF frequency detected by the Vpp detector in each of the plurality of phases, and (e) adjusting the power level of at least one of the first RF signal or the second pulsed RF signal in the at least one selected phase so that the representative value of the bias Vpp value of the second RF frequency reaches the target value, based on the power levels set in each of (a1) and (a2) and the representative value of the bias Vpp value of the second RF frequency acquired in (d). As a result, the process stability may be enhanced.

Further, according to the third embodiment, the plasma processing apparatus 1a further includes the third RF power supply (the third RF generator 31e) coupled to the RF electrode and configured to generate the third pulsed RF signal having at least two power levels in each of the plurality of pulse cycles. The controller 2 is configured to perform (a3) setting the at least two power levels of the third pulsed RF signal. The controller 2 adjusts, in (e), the power level of at least one of the first RF signal, the second pulsed RF signal or the third pulsed RF signal in the at least one selected phase so that the representative value of the bias Vpp value of the second RF frequency reaches the target value, based on the power levels set in each of (a1) to (a3) and the representative value of the bias Vpp value of the second RF frequency acquired in (d). As a result, even if two types of bias RF power supplies are provided, the process stability may be enhanced.

Further, according to the third embodiment, the representative value is an average value of a plurality of bias Vpp values of the second RF frequency detected by the Vpp detector over an entire period of the phase. As a result, the accuracy of the representative value of the bias Vpp may be enhanced.

Further, according to the third embodiment, the representative value is an average value of a plurality of bias Vpp values of the second RF frequency detected by the Vpp detector over a detection period after a delay time in the phase so that a bias Vpp value in a transient state is excluded from the plurality of bias Vpp values. As a result, the accuracy of the representative value of the bias Vpp value may be enhanced.

Further, according to the third embodiment, the representative value is an average value of selected bias Vpp values within a set Vpp range, among a plurality of bias Vpp values of the second RF frequency detected by the Vpp detector over an entire period of the phase so that a bias Vpp value in a transient state is excluded from the plurality of bias Vpp values. As a result, the accuracy of the representative value of the bias Vpp value may be enhanced.

Further, according to the fourth embodiment, the plasma processing apparatus 1 includes: the chamber (the plasma processing chamber 10); the substrate support 11 disposed in the chamber and including the RF electrode; the RF power supply (the second RF generator 31b) coupled to the RF electrode and configured to generate a pulsed RF signal, wherein the pulsed RF signal has, in each of a plurality of pulse cycles, the first power level during the first period, the second power level during the second period, and the third power level during the third period; the Vpp detector (the gauge 35) configured to detect the bias Vpp value between the RF power supply and the RF electrode; and the controller 2. The controller 2 is configured to perform (a) setting the first power level, the second power level, and the third power level, (b) setting the bias Vpp target value during at least one period selected from the first period, the second period, and the third period, (c1) acquiring the first representative value of the bias Vpp value detected by the Vpp detector during the first period, (c2) acquiring the second representative value of the bias Vpp value detected by the Vpp detector during the second period, (c3) acquiring the third representative value of the bias Vpp value detected by the Vpp detector during the third period, and (d) adjusting the power level of the pulsed RF signal based on the first power level, the second power level, and the third power level set in (a) and the first representative value, the second representative value, and the third representative value acquired in (c1) to (c3). As a result, the process stability may be enhanced.

Further, according to the fourth embodiment, at least one of the first representative value, the second representative value, or the third representative value is an average value of a plurality of bias Vpp values detected by the Vpp detector over the entirety of the respective period among the first period, the second period, and the third period. As a result, the accuracy of at least one of the first representative value, the second representative value, or the third representative value of the bias Vpp values may be enhanced.

Further, according to the fourth embodiment, at least one of the first representative value, the second representative value, or the third representative value is an average value of a plurality of bias Vpp values detected by the Vpp detector over a detection period after a delay time during a respective period among the first period, the second period, and the third period so that the bias Vpp value in a transient state is excluded from the plurality of bias Vpp values. As a result, the accuracy of at least one of the first representative value, the second representative value, or the third representative value of the bias Vpp values may be enhanced.

Further, according to the fourth embodiment, at least one of the first representative value, the second representative value, or the third representative value is an average value of selected bias Vpp values within a set Vpp range, among a plurality of bias Vpp values detected by the Vpp detector over the entirety of a respective period among the first period, the second period, and the third period so that a bias Vpp value in a transient state is excluded from the plurality of bias Vpp values. As a result, the accuracy of at least one of the first representative value, the second representative value, or the third representative value of the bias Vpp values may be enhanced.

Further, according to the fourth embodiment, one of the first power level, the second power level, and the third power level is a zero power level. As a result, even in a pulse cycle that includes a period with a zero power level, the process stability may be enhanced.

Further, according to the fourth embodiment, the pulsed RF signal is controlled so that the bias Vpp value remains constant. As a result, the process stability may be enhanced.

Further, according to the fourth embodiment, the pulsed RF signal is controlled so that the input power of the power level remains constant. As a result, the power level may be easily controlled.

Further, according to Modification 2 of the fourth embodiment, the plasma processing apparatus 1 includes: the chamber (the plasma processing chamber 10); the substrate support 11 disposed in the chamber and including the RF electrode; the RF power supply (the second RF generator 31b) coupled to the RF electrode and configured to generate the pulsed RF signal, wherein the pulsed RF signal has, in each of a plurality of pulse cycles, the first power level during the first period and the second power level during the second period; the Vpp detector (the gauge 35) configured to detect the bias Vpp value between the RF power supply and the RF electrode; and the controller 2. The controller 2 is configured to perform (a) setting the first power level and the second power level, (c) acquiring the first representative value of the bias Vpp value detected by the Vpp detector during the first period, wherein the first representative value is determined based on a plurality of bias Vpp values detected by the Vpp detector in a cycle greater than or equal to 10 times a pulse frequency of the plurality of pulse cycles, and (d) adjusting the power level of the pulsed RF signal based on the first power level set in (a) and the first representative value acquired in (c). As a result, the process stability may be enhanced.

Each embodiment disclosed herein should be considered to be exemplary and not limitative in all respects. Each embodiment described above may be omitted, replaced or modified in various embodiments without departing from the scope of the appended claims and their gist.

Further, in each of the above embodiments, the case in which the gauge 35 is provided in the conductor 33b connected to the substrate support 11 has been described by way of example. However, the present disclosure is not limited thereto. The gauge 35 may be provided on an electrode disposed in the plasma processing chamber 10 or wiring connected to the electrode to measure the state of plasma in the interior of the plasma processing chamber 10. For example, the gauge 35 may be provided on the conductor 33a connected to the antenna 14. Further, a measurement electrode may be disposed in the plasma processing chamber 10, and the gauge 35 may be provided on the electrode or wiring connected to the electrode. Further, in the present embodiment, the gauge 35 is provided closer to the substrate support 11 than the impedance matching circuit 34b of the conductor 33b. Thus, the gauge 35 may measure the state of plasma in the interior of the plasma processing chamber 10.

Further, in each of the above embodiments, the plasma processing apparatus 1 which performs processing such as etching on the substrate W using inductively coupled plasma as a plasma source has been described by way of example, but the disclosed technique is not limited thereto. Various types of plasma sources such as capacitively coupled plasma, microwave plasma, magnetron plasma, and the like may be employed as long as it processes the substrate W using plasma. For example, a capacitively coupled plasma (CCP) processing apparatus includes an upper electrode and a lower electrode. The lower electrode is embedded in the substrate support and the upper electrode is positioned above the substrate support. Further, a first matcher is coupled to either the upper electrode or the lower electrode, and a second matcher is coupled to the lower electrode. Accordingly, the first matcher is coupled to one of the antenna 14 of the inductively coupled plasma processing apparatus 1, the upper electrode of the capacitively coupled plasma processing apparatus, and the lower electrode of the capacitively coupled plasma processing apparatus. In other words, the first matcher is coupled to the plasma processing chamber 10. Accordingly, the first RF power supply is coupled, via the first matcher, to one of the antenna 14 of the inductively coupled plasma processing apparatus 1, the upper electrode of the capacitively coupled plasma processing apparatus, and the lower electrode of the capacitively coupled plasma processing apparatus. In other words, the first RF power supply is coupled to the plasma processing chamber 10 via the first matcher.

In addition, individual constituent elements of each apparatus illustrated herein do not necessarily have to be physically configured as illustrated. In other words, specific distributed/integrated forms of each apparatus are not limited to the illustrations, and some or all of the constituent elements may be configured to be functionally or physically distributed/integrated in any unit, depending on various types of loads or usage conditions.

Further, various processing functions performed by each apparatus may be executed entirely or partially on a CPU (or a microcomputer such as a micro processing unit (MPU) or micro controller unit (MCU)). Further, all or any portion of these various processing functions may be implemented by a program analyzed and executed by the CPU (or MPU, MCU, or similar microcomputer) or may be implemented as hardware by wired logic.

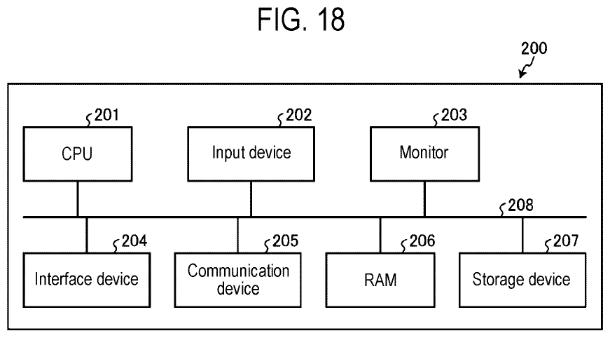

The various types of processing described in each of the above embodiments may be implemented by executing a pre-prepared program on a computer. Accordingly, an example of a computer that executes a program with functionalities similar to those described in the above embodiments will be described below. FIG. 18 is a diagram illustrating an example of a computer that executes an adjustment program.

As illustrated in FIG. 18, a computer 200 includes a CPU 201 for executing various computational processes, an input device 202 for receiving data input, and a monitor 203. Further, the computer 200 includes an interface device 204 for connection with various apparatuses, and a communication device 205 for connection with other information processing apparatuses in a wired or wireless manner. Further, the computer 200 includes a RAM 206 for temporarily storing various information, and a storage device 207. Further, these devices 201 to 207 are connected to a bus 208.

The storage device 207 stores the adjustment program with functionalities similar to processors such as the setter 131, the determiner 132, the acquisiter 133, and the adjuster 134 as illustrated in FIG. 2. Further, the storage device 207 stores data similar to the data stored in the storage 2a2 such as recipe data and the set power level of at least one of the source RF signal or the bias RF signal. For example, the input device 202 receives various information such as operational information, which is input by a process manager who is the user of the computer 200. For example, the monitor 203 displays various screens such as a display screen with respect to the process manager who is the user of the computer 200. The interface device 204 is connected to, for example, a printing device. The communication device 205 has, for example, the same function as the external interface 2a3 illustrated in FIG. 2, and exchanges various information with other functional parts such as the gauge 35 and the synchronization signal generator 31c.

The CPU 201 performs various types of processing by reading each program stored in the storage device 207 and deploying and executing the same on the RAM 206. Further, these programs enable the computer 200 to function as the setter 131, the determiner 132, the acquisiter 133, and the adjuster 134 as illustrated in FIG. 2.

In addition, the aforementioned adjustment program does not necessarily need to be stored in the storage device 207. For example, the computer 200 may read and execute a program stored in a non-transitory storage medium readable by the computer 200. Examples of the storage medium readable by the computer 200 may include portable storage media such as CD-ROMs, DVDs, and universal serial bus (USB) memories, semiconductor memories such as flash memories, and hard disk drives. Further, a parameter selection program may be stored in a device connected to public networks, the Internet, a LAN or the like, and the computer 200 may read and execute the parameter selection program from the device.

In addition, the present disclosure may also adopt the following configurations.

(1)

A plasma processing apparatus includes:
a chamber;
a substrate support disposed in the chamber and including a radio-frequency (RF) electrode;
a first RF power supply coupled to the chamber and configured to generate a first pulsed RF signal having at least two power levels in each of a plurality of pulse cycles;
a second RF power supply coupled to the RF electrode and configured to generate a second pulsed RF signal having at least two power levels in each of the plurality of pulse cycles;
a Vpp detector configured to detect a bias Vpp value between the second RF power supply and the RF electrode; and
a controller configured to perform:
   (a1) setting the at least two power levels of the first pulsed RF signal;
   (a2) setting the at least two power levels of the second pulsed RF signal;
   (b) determining a plurality of phases in one pulse cycle of the plurality of pulse cycles, wherein a state of at least one of the first pulsed RF signal or the second pulsed RF signal in each of the plurality of phases differs from a state in an adjacent phase;
   (c) setting a bias Vpp target value in at least one phase selected from the plurality of phases determined in (b);
   (d) acquiring a representative value of the bias Vpp value detected by the Vpp detector in each of the plurality of phases; and
   (e) adjusting the power level of at least one of the first pulsed RF signal or the second pulsed RF signal in the at least one selected phase so that the representative value of the bias Vpp value reaches the bias Vpp target value, based on the power levels set in each of (a1) and (a2) and the representative value of the bias Vpp value acquired in (d).
      (2)

In the plasma processing apparatus of (1) above, the representative value is an average value of a plurality of bias Vpp values detected by the Vpp detector over an entire period of the phase.

(3)

In the plasma processing apparatus of (1) above, the representative value is an average value of a plurality of bias Vpp values detected by the Vpp detector over a detection period after a delay time in the phase so that a bias Vpp value in a transient state is excluded from the plurality of bias Vpp values.

(4)

In the plasma processing apparatus of (1) above, the representative value is an average value of selected bias Vpp values within a set Vpp range, among a plurality of bias Vpp values detected by the Vpp detector over an entire period of the phase so that a bias Vpp value in a transient state is excluded from the plurality of bias Vpp values.

(5)

In the plasma processing apparatus of any one of (2) to (4) above, the plurality of bias Vpp values are detected continuously at a regular interval.

(6)

In the plasma processing apparatus of any one of (2) to (5) above, the plurality of bias Vpp values are detected in a cycle greater than or equal to 10 times a pulse frequency of the plurality of pulse cycles.

(7)

The plasma processing apparatus of (3) above further includes a synchronization signal generator configured to generate a synchronization signal for synchronizing the first RF power supply and the second RF power supply,
wherein the controller is configured to perform determining the delay time and the detection period in the phase based on the synchronization signal.
   (8)

A plasma processing apparatus includes:
a chamber;
a substrate support disposed in the chamber and including an RF electrode;
a first RF power supply coupled to the chamber and configured to generate a first pulsed RF signal having at least two power levels in each of a plurality of pulse cycles, wherein the first pulsed RF signal has a first RF frequency;
a second RF power supply coupled to the RF electrode and configured to generate a second pulsed RF signal having at least two power levels in each of the plurality of pulse cycles, wherein the second pulsed RF signal has a second RF frequency;
a third RF power supply coupled to the RF electrode and configured to generate a third pulsed RF signal having at least two power levels in each of the plurality of pulse cycles, wherein the third pulsed RF signal has a third RF frequency;
a Vpp detector configured to detect a bias Vpp value between the second RF power supply and the third RF power supply and the RF electrode; and
a controller configured to perform:
   (a1) setting the at least two power levels of the first pulsed RF signal;
   (a2) setting the at least two power levels of the second pulsed RF signal;
   (a3) setting the at least two power levels of the third pulsed RF signal;
   (b) determining a plurality of phases in one pulse cycle of the plurality of pulse cycles, wherein a state of at least one of the first pulsed RF signal, the second pulsed RF signal, or the third pulsed RF signal in each of the plurality of phases differs from a state in an adjacent phase;
   (c) setting a bias Vpp target value of at least one of the second RF frequency or the third RF frequency in at least one phase selected from the plurality of phases determined in (b);
   (d) acquiring a representative value of the bias Vpp value of at least one of the second RF frequency or the third RF frequency, which is detected by the Vpp detector, in each of the plurality of phases; and
   (e) adjusting the power level of at least one of the first pulsed RF signal, the second pulsed RF signal, or the third pulsed RF signal in the at least one selected phase so that the representative value of the bias Vpp value of one of the second RF frequency and the third RF frequency reaches the bias Vpp target value, based on the power levels set in each of (a1) to (a3) and the representative value of the bias Vpp value of at least one of the second RF frequency or the third RF frequency acquired in (d).
      (9)

In the plasma processing apparatus of (8) above, the representative value is an average value of a plurality of bias Vpp values of one of the second RF frequency and the third RF frequency, which is detected by the Vpp detector over an entire period of the phase.

(10)

In the plasma processing apparatus of (8) above, the representative value is an average value of a plurality of bias Vpp values of one of the second RF frequency and the third RF frequency, which is detected by the Vpp detector over a detection period after a delay time in the phase so that a bias Vpp value in a transient state is excluded from the plurality of bias Vpp values.

(11)

In the plasma processing apparatus of (8) above, the representative value is an average value of selected bias Vpp values in a set Vpp range, among a plurality of bias Vpp values of one of the second RF frequency and the third RF frequency, which is detected by the Vpp detector over an entire period of the phase so that a bias Vpp value in a transient state is excluded from the plurality of bias Vpp values.

(12)

In the plasma processing apparatus of any one of (9) to (1) above, the plurality of bias Vpp values are detected in a cycle greater than or equal to 10 times a pulse frequency of the plurality of pulse cycles.

(13)

In the plasma processing apparatus of (10) above further includes a synchronization signal generator configured to generate a synchronization signal for synchronizing the first RF power supply, the second RF power supply, and the third RF power supply,
wherein the controller is configured to perform determining the delay time and the detection period in the phase based on the synchronization signal.
   (14)

In the plasma processing apparatus of any one of (8) to (13) above, the second pulsed RF signal is controlled so that an input power of the power level remains constant, and
wherein the third pulsed RF signal is controlled so that the bias Vpp value remains constant.
   (15)

A plasma processing apparatus includes:
a chamber;
a substrate support disposed in the chamber and including an RF electrode;
a first RF power supply coupled to the chamber and configured to generate a first RF signal, wherein the first RF signal has a first RF frequency;
a second RF power supply coupled to the RF electrode and configured to generate a second pulsed RF signal having at least two power levels in each of a plurality of pulse cycles, wherein the second pulsed RF signal has a second RF frequency;
a Vpp detector configured to detect a bias Vpp value between the second RF power supply and the RF electrode; and
a controller configured to perform:
   (a1) setting a power level of the first RF signal;
   (a2) setting the at least two power levels of the second pulsed RF signal;
   (b) determining a plurality of phases in one pulse cycle of the plurality of pulse cycles, wherein a state of the second pulsed RF signal in each of the plurality of phases differs from a state in an adjacent phase;
   (c) setting a bias Vpp target value of the second RF frequency in at least one phase selected from the plurality of phases determined in (b);
   (d) acquiring a representative value of the bias Vpp value of the second RF frequency detected by the Vpp detector in each of the plurality of phases; and
   (e) adjusting the power level of at least one of the first RF signal or the second pulsed RF signal in the at least one selected phase so that the representative value of the bias Vpp value of the second RF frequency reaches the bias Vpp target value, based on the power levels set in (a1) and (a2) and the representative value of the bias Vpp value of the second RF frequency acquired in (d).
      (16)

In the plasma processing apparatus of (15) above further includes a third RF power supply coupled to the RF electrode and configured to generate a third pulsed RF signal having at least two power levels in each of the plurality of pulse cycles,
wherein the controller is configured to perform (a3) setting the at least two power levels of the third pulsed RF signal, and
wherein the controller adjusts, in (e), the power level of at least one of the first RF signal, the second pulsed RF signal or the third pulsed RF signal in the at least one selected phase so that the representative value of the bias Vpp value of the second RF frequency reaches the bias Vpp target value, based on the power levels set in (a1) to (a3) and the representative value of the bias Vpp value of the second RF frequency acquired in (d).
   (17)

In the plasma processing apparatus of (15) or (16) above, the representative value is an average value of a plurality of bias Vpp values of the second RF frequency detected by the Vpp detector over an entire period of the phase.

(18)

In the plasma processing apparatus of (15) or (16) above, the representative value is an average value of a plurality of bias Vpp values of the second RF frequency detected by the Vpp detector over a detection period after a delay time in the phase so that a bias Vpp value in a transient state is excluded from the plurality of bias Vpp values.

(19)

In the plasma processing apparatus of (15) or (16) above, the representative value is an average value of selected bias Vpp values within a set Vpp range, among a plurality of bias Vpp values of the second RF frequency detected by the Vpp detector over an entire period of the phase so that a bias Vpp value in a transient state is excluded from the plurality of bias Vpp values.

(20)

A plasma processing apparatus includes:
a chamber;
a substrate support disposed in the chamber and including an RF electrode;
an RF power supply coupled to the RF electrode and configured to generate a pulsed RF signal, wherein the pulsed RF signal has, in each of a plurality of pulse cycles, a first power level during a first period, a second power level during a second period, and a third power level during a third period;
a Vpp detector configured to detect a bias Vpp value between the RF power supply and the RF electrode; and
a controller configured to perform:
   (a) setting the first power level, the second power level, and the third power level;
   (b) setting a bias Vpp target value during at least one period selected from the first period, the second period, and the third period;
   (c1) acquiring a first representative value of the bias Vpp value detected by the Vpp detector during the first period;
   (c2) acquiring a second representative value of the bias Vpp value detected by the Vpp detector during the second period;
   (c3) acquiring a third representative value of the bias Vpp value detected by the Vpp detector during the third period; and
   (d) adjusting the power level of the pulsed RF signal based on the first power level, the second power level, and the third power level set in (a) and the first representative value, the second representative value, and the third representative value acquired in (c1) to (c3).
      (21)

In the plasma processing apparatus of (20) above, at least one of the first representative value, the second representative value, or the third representative value is an average value of a plurality of bias Vpp values detected by the Vpp detector over the entirety of a respective period among the first period, the second period, and the third period.

(22)

In the plasma processing apparatus of (20) or (21) above, at least one of the first representative value, the second representative value, or the third representative value is an average value of a plurality of bias Vpp values detected by the Vpp detector over a detection period after a delay time during a corresponding period among the first period, the second period, and the third period so that a bias Vpp value in a transient state is excluded from the plurality of bias Vpp values.

(23)

In the plasma processing apparatus of any one of (20) to (22) above, at least one of the first representative value, the second representative value, or the third representative value is an average value of selected bias Vpp values within a set Vpp range, among a plurality of bias Vpp values detected by the Vpp detector over the entirety of a respective period among the first period, the second period, and the third period so that a bias Vpp value in a transient state is excluded from the plurality of bias Vpp values.

(24)

In the plasma processing apparatus of any one of (21) to (23) above, the plurality of bias Vpp values are detected in a cycle greater than or equal to 10 times a pulse frequency of the plurality of pulse cycles.

(25)

In the plasma processing apparatus of any one of (20) to (24) above, one of the first power level, the second power level, and the third power level is a zero power level.

(26)

In the plasma processing apparatus of any one of (20) to (25) above, the pulsed RF signal is controlled so that the bias Vpp value remains constant.

(27)

In the plasma processing apparatus of any one of (20) to (26) above, the pulsed RF signal is controlled so that an input power of the power level remains constant.

(28)

A plasma processing apparatus includes:
a chamber;
a substrate support disposed in the chamber and including an RF electrode;
an RF power supply coupled to the RF electrode and configured to generate a pulsed RF signal, wherein the pulsed RF signal has, in each of a plurality of pulse cycles, a first power level during a first period and a second power level during a second period;
a Vpp detector configured to detect a bias Vpp value between the RF power supply and the RF electrode; and
a controller configured to perform:
   (a) setting the first power level and the second power level;
   (c) acquiring a first representative value of the bias Vpp value detected by the Vpp detector during the first period, wherein the first representative value is determined based on a plurality of bias Vpp values detected by the Vpp detector in a cycle greater than or equal to 10 times a pulse frequency of the plurality of pulse cycles; and
   (d) adjusting the power level of the pulsed RF signal based on the first power level set in (a) and the first representative value acquired in (c).
      (29)

In the plasma processing apparatus of (28) above, the first representative value is an average value of the plurality of bias Vpp values detected by the Vpp detector over the entire first period.

(30)

In the plasma processing apparatus of (28) above, the first representative value is an average value of the plurality of bias Vpp values detected by the Vpp detector over a detection period after a delay time in the first period so that a bias Vpp value in a transient state is excluded from the plurality of bias Vpp values.

(31)

In the plasma processing apparatus of (28) above, the first representative value is an average value of selected bias Vpp values within a set Vpp range, among the plurality of bias Vpp values detected by the Vpp detector over the entire first period so that a bias Vpp value in a transient state is excluded from the plurality of bias Vpp values.

(32)

In the plasma processing apparatus of any one of (28) to (31) above, the second power level is a zero power level.

According to the present disclosure in some embodiments, it is possible to enhance the stability of a process.

While certain embodiments have been described, these embodiments have been presented by way of example only, and are not intended to limit the scope of the disclosures. Indeed, the embodiments described herein may be embodied in a variety of other forms. Further, various omissions, substitutions and changes in the form of the embodiments described herein may be made without departing from the spirit of the disclosures. The accompanying claims and their equivalents are intended to cover such forms or Modifications as would fall within the scope and spirit of the disclosures.

What is claimed is:

1. A plasma processing apparatus, comprising:
a chamber;
a substrate support disposed in the chamber and including a radio-frequency (RF) electrode;
a first RF power supply coupled to the chamber and configured to generate a first pulsed RF signal having at least two power levels in each of a plurality of pulse cycles;
a second RF power supply coupled to the RF electrode and configured to generate a second pulsed RF signal having at least two power levels in each of the plurality of pulse cycles;
a voltage (Vpp) detector configured to detect a bias Vpp value between the second RF power supply and the RF electrode; and
a controller configured to perform:
(a1) setting the at least two power levels of the first pulsed RF signal;
(a2) setting the at least two power levels of the second pulsed RF signal;
(b) determining a plurality of phases in one pulse cycle of the plurality of pulse cycles, wherein a state of at least one of the first pulsed RF signal or the second pulsed RF signal in each of the plurality of phases differs from a state in an adjacent phase;
(c) setting a bias Vpp target value in at least one phase selected from the plurality of phases determined in (b);
(d) acquiring a representative value of the bias Vpp value detected by the Vpp detector in each of the plurality of phases; and
(e) adjusting the power level of at least one of the first pulsed RF signal or the second pulsed RF signal in the at least one selected phase so that the representative value of the bias Vpp value reaches the bias Vpp target value, based on the power levels set in each of (a1) and (a2) and the representative value of the bias Vpp value acquired in (d).

2. The plasma processing apparatus of claim 1, wherein the representative value is an average value of a plurality of bias Vpp values detected by the Vpp detector over an entire period of the phase.

3. The plasma processing apparatus of claim 1, wherein the representative value is an average value of a plurality of bias Vpp values detected by the Vpp detector over a detection period after a delay time in the phase so that a bias Vpp value in a transient state is excluded from the plurality of bias Vpp values.

4. The plasma processing apparatus of claim 1, wherein the representative value is an average value of selected bias Vpp values within a set Vpp range, among a plurality of bias Vpp values detected by the Vpp detector over an entire period of the phase so that a bias Vpp value in a transient state is excluded from the plurality of bias Vpp values.

5. The plasma processing apparatus of claim 2, wherein the plurality of bias Vpp values are detected continuously at a regular interval.

6. The plasma processing apparatus of claim 2, wherein the plurality of bias Vpp values are detected in a cycle greater than or equal to 10 times a pulse frequency of the plurality of pulse cycles.

7. The plasma processing apparatus of claim 3, further comprising: a synchronization signal generator configured to generate a synchronization signal for synchronizing the first RF power supply and the second RF power supply,
wherein the controller is configured to perform determining the delay time and the detection period in the phase based on the synchronization signal.

8. A plasma processing apparatus, comprising:
a chamber;
a substrate support disposed in the chamber and including an RF electrode;
a first RF power supply coupled to the chamber and configured to generate a first pulsed RF signal having at least two power levels in each of a plurality of pulse cycles, the first pulsed RF signal having a first RF frequency;
a second RF power supply coupled to the RF electrode and configured to generate a second pulsed RF signal having at least two power levels in each of the plurality of pulse cycles, the second pulsed RF signal having a second RF frequency;
a third RF power supply coupled to the RF electrode and configured to generate a third pulsed RF signal having at least two power levels in each of the plurality of pulse cycles, the third pulsed RF signal having a third RF frequency;
a Vpp detector configured to detect a bias Vpp value between the second RF power supply and the third RF power supply and the RF electrode; and
a controller configured to perform:
(a1) setting the at least two power levels of the first pulsed RF signal;
(a2) setting the at least two power levels of the second pulsed RF signal;
(a3) setting the at least two power levels of the third pulsed RF signal;
(b) determining a plurality of phases in one pulse cycle of the plurality of pulse cycles, wherein a state of at least one of the first pulsed RF signal, the second pulsed RF signal, or the third pulsed RF signal in each of the plurality of phases differs from a state in an adjacent phase;
(c) setting a bias Vpp target value of at least one of the second RF frequency or the third RF frequency in at least one phase selected from the plurality of phases determined in (b);
(d) acquiring a representative value of the bias Vpp value of at least one of the second RF frequency or the third RF frequency, which is detected by the Vpp detector, in each of the plurality of phases; and
(e) adjusting the power level of at least one of the first pulsed RF signal, the second pulsed RF signal, or the third pulsed RF signal in the at least one selected phase so that the representative value of the bias Vpp value of one of the second RF frequency and the third RF frequency reaches the bias Vpp target value, based on the power levels set in each of (a1) to (a3) and the representative value of the bias Vpp value of at least one of the second RF frequency or the third RF frequency acquired in (d).

9. The plasma processing apparatus of claim 8, wherein the representative value is an average value of a plurality of bias Vpp values of one of the second RF frequency and the third RF frequency, which is detected by the Vpp detector over an entire period of the phase.

10. The plasma processing apparatus of claim 8, wherein the representative value is an average value of a plurality of bias Vpp values of one of the second RF frequency and the third RF frequency, which is detected by the Vpp detector over a detection period after a delay time in the phase so that a bias Vpp value in a transient state is excluded from the plurality of bias Vpp values.

11. The plasma processing apparatus of claim 8, wherein the representative value is an average value of selected bias Vpp values in a set Vpp range, among a plurality of bias Vpp values of one of the second RF frequency and the third RF frequency, which is detected by the Vpp detector over an entire period of the phase so that a bias Vpp value in a transient state is excluded from the plurality of bias Vpp values.

12. The plasma processing apparatus of claim 9, wherein the plurality of bias Vpp values are detected in a cycle greater than or equal to 10 times a pulse frequency of the plurality of pulse cycles.

13. The plasma processing apparatus of claim 10, further comprising: a synchronization signal generator configured to generate a synchronization signal for synchronizing the first RF power supply, the second RF power supply, and the third RF power supply,
wherein the controller is configured to perform determining the delay time and the detection period in the phase based on the synchronization signal.

14. The plasma processing apparatus of claim 8, wherein the second pulsed RF signal is controlled so that an input power of the power level remains constant, and
wherein the third pulsed RF signal is controlled so that the bias Vpp value remains constant.

15. A plasma processing apparatus, comprising:
a chamber;
a substrate support disposed in the chamber and including an RF electrode;
a first RF power supply coupled to the chamber and configured to generate a first RF signal, the first RF signal having a first RF frequency;
a second RF power supply coupled to the RF electrode and configured to generate a second pulsed RF signal having at least two power levels in each of a plurality of pulse cycles, the second pulsed RF signal having a second RF frequency;
a Vpp detector configured to detect a bias Vpp value between the second RF power supply and the RF electrode; and
a controller configured to perform:
(a1) setting a power level of the first RF signal;
(a2) setting the at least two power levels of the second pulsed RF signal;
(b) determining a plurality of phases in one pulse cycle of the plurality of pulse cycles, wherein a state of the second pulsed RF signal in each of the plurality of phases differs from a state in an adjacent phase;
(c) setting a bias Vpp target value of the second RF frequency in at least one phase selected from the plurality of phases determined in (b);
(d) acquiring a representative value of the bias Vpp value of the second RF frequency detected by the Vpp detector in each of the plurality of phases; and
(e) adjusting the power level of at least one of the first RF signal or the second pulsed RF signal in the at least one selected phase so that the representative value of the bias Vpp value of the second RF frequency reaches the bias Vpp target value, based on the power levels set in (a1) and (a2) and the representative value of the bias Vpp value of the second RF frequency acquired in (d).

16. The plasma processing apparatus of claim 15, further comprising: a third RF power supply coupled to the RF electrode and configured to generate a third pulsed RF signal having at least two power levels in each of the plurality of pulse cycles,
wherein the controller is configured to perform (a3) setting the at least two power levels of the third pulsed RF signal, and
wherein the controller adjusts, in (e), the power level of at least one of the first RF signal, the second pulsed RF signal or the third pulsed RF signal in the at least one selected phase so that the representative value of the bias Vpp value of the second RF frequency reaches the bias Vpp target value, based on the power levels set in (a1) to (a3) and the representative value of the bias Vpp value of the second RF frequency acquired in (d).

17. The plasma processing apparatus of claim 15, wherein the representative value is an average value of a plurality of bias Vpp values of the second RF frequency detected by the Vpp detector over an entire period of the phase.

18. The plasma processing apparatus of claim 15, wherein the representative value is an average value of a plurality of bias Vpp values of the second RF frequency detected by the Vpp detector over a detection period after a delay time in the phase so that a bias Vpp value in a transient state is excluded from the plurality of bias Vpp values.

19. The plasma processing apparatus of claim 15, wherein the representative value is an average value of selected bias Vpp values within a set Vpp range, among a plurality of bias Vpp values of the second RF frequency detected by the Vpp detector over an entire period of the phase so that a bias Vpp value in a transient state is excluded from the plurality of bias Vpp values.
